(19) United States
(12) Patent Application Publication
(10) Pub. No.: US 2023/0282264 A1
(43) Pub. Date: Sep. 7, 2023

(54) Memory Arrays, Methods of Forming the Same, and Methods of Operating the Same

(71) Applicants: Taiwan Semiconductor Manufacturing Co., Ltd., Hsinchu (TW); The Board of Trustees of the Leland Stanford Junior University, Stanford, CA (US)

(72) Inventors: Tzu-Chiang Chen, Hsinchu (TW); MingYuan Song, Hsinchu (TW); William San-Hsi Hwang, Seattle, WA (US); Shan Xiang Wang, Portola Valley, CA (US)

(21) Appl. No.: 18/154,244

(22) Filed: Jan. 13, 2023

Related U.S. Application Data
(60) Provisional application No. 63/268,930, filed on Mar. 7, 2022.

(51) Int. Cl. G11C 11/16; H01L 23/528; H10B 61/00; H10N 50/01; H10N 50/10

(52) U.S. Cl. CPC G11C 11/1675; G11C 11/1655; G11C 11/1673; H01L 23/5283; H10B 61/20; H10N 50/01; H10N 50/10

(57) ABSTRACT

In an embodiment, a device includes: a spin-orbit torque line; a write transistor coupling a first end of the spin-orbit torque line to a first source line; a source transistor coupling a second end of the spin-orbit torque line to a second source line; and a plurality of magnetic tunnel junctions coupled to the spin-orbit torque line, the magnetic tunnel junctions being in a current path between the write transistor and the source transistor.

### PRIORITY CLAIM AND CROSS-REFERENCE

This application claims the benefit of U.S. Provisional Application No. 63/268,930, filed on Mar. 7, 2022, which application is hereby incorporated herein by reference.

### BACKGROUND

Magnetic random access memory (MRAM) is one of the leading candidates for next-generation memory technologies that aim to surpass the performance of various existing memories. MRAM offers comparable performance to volatile static random access memory (SRAM) and comparable density with lower power consumption to volatile dynamic random access memory (DRAM). As compared to non-volatile flash memory, MRAM offers much faster access speed and suffers minimal degradation over time. Spin orbit torque MRAM (SOT-MRAM) is a type of MRAM. As compared to spin transfer torque MRAM (STT-MRAM), which is another type of MRAM, SOT-MRAM offers better performance in terms of speed and endurance. Nevertheless, further reducing switching energy of SOT-MRAM is limited.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a memory device 100, in accordance with some embodiments.

FIG. 2A illustrates a write path of unit cells in a memory device, in accordance with some embodiments.

FIG. 2B illustrates a read path of unit cells in a memory device, in accordance with some embodiments.

FIG. 3 is a three-dimensional view of a memory device, in accordance with some embodiments.

FIGS. 4A-14D are view of intermediate stages in the manufacturing of a memory device, in accordance with some embodiments.

FIG. 15 is a three-dimensional view of a memory device, in accordance with some embodiments.

FIGS. 16A-23D are view of intermediate stages in the manufacturing of a memory device, in accordance with some embodiments.

FIG. 24 is a three-dimensional view of a memory device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a magnetic random access memory (MRAM) device includes strings of unit cells. Each string of unit cells includes a spin-orbit torque line and a plurality of magnetic tunnel junctions (MTJs). The MTJs of a string are simultaneously programmed by applying an in-plane charge current to the spin-orbit torque line of the string and also applying a spin transfer current to each MTJ of the string. In this way, the MRAM device is a spin transfer torque-assisted spin-orbit torque MRAM device that has a high switching speed and thus a low write latency. The MTJs are interconnected by metallization patterns with a layout that allows for a high unit cell density.

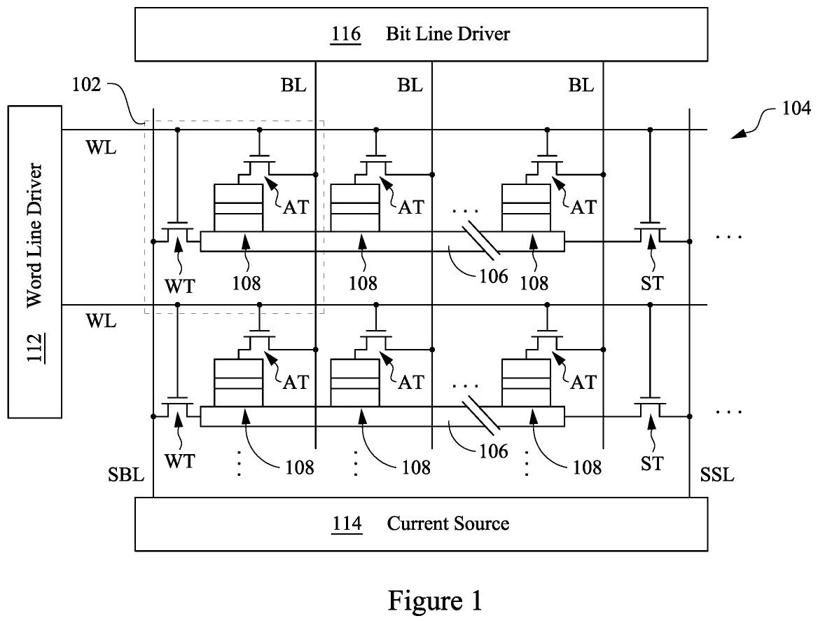

FIG. 1 is a schematic diagram of a memory device 100, in accordance with some embodiments. The memory device 100 is a magnetic random access memory (MRAM) device. The memory device 100 includes a memory array 104 of unit cells 102 arranged along rows and columns. The unit cells 102 in each row may be arranged along a first direction, while the unit cells 102 in each column may be arranged along a second direction. Each row of the unit cells 102 is coupled to a word line WL, a string bit line SBL, and a string source line SSL. Each column of the unit cells 102 is coupled to a bit line BL. The word lines WL, the bit lines BL, the string bit lines SBL, and the string source lines SSL are conductive lines. Each unit cell 102 may be defined between one of the word lines WL, one of the string bit lines SBL, one of the string source lines SSL, and one of the bit lines BL. In addition, the word lines WL may extend along the direction of the rows, and the bit lines BL, the string bit lines SBL, and the string source lines SSL may extend along the direction of the columns.

Each unit cell 102 includes a magnetic tunnel junction (MTJ) 108. The MTJ 108 acts as a storage element. Magnetization orientations of ferromagnetic layers in the MTJ 108 determine an electrical resistance of the MTJ 108. The MTJ 108 has a low-electrical resistance state when the magnetization orientations of its ferromagnetic layers are in a parallel state. The MTJ 108 has a high-electrical resistance state when the magnetization orientations of its ferromagnetic layers are in an anti-parallel state. By altering the magnetization orientations of the ferromagnetic layers in the MTJ 108, the MTJ 108 can be programmed to store complementary logic states (e.g., the high-electrical resistance state indicating a logic high state and the low-electrical resistance state indicating a logic low state).

The MTJs 108 may be perpendicular MTJs, in-plane MTJs, or the like. The MTJs 108 may be programmed by utilizing a spin Hall effect. Each MTJ 108 is formed on a portion of a spin-orbit torque (SOT) line 106, such that the MTJ 108 of each unit cell 102 is coupled to the SOT line 106 for that unit cell 102. The SOT line 106 may be referred to as a spin hall electrode (SHE), a spin hall structure, or an SOT structure, and is used to switch a magnetization orientation and electrical resistance of an MTJ 108. During a programming operation, an in-plane charge current passing through the SOT line 106 is converted to a perpendicular spin current via the spin Hall effect. The perpendicular spin current flows along a ferromagnetic layer of the MTJ 108 and changes the magnetization orientation of the ferromagnetic layer via spin-orbit torque (SOT). In this way, the magnetization orientations of the MTJ 108 (e.g., the electrical resistance of the MTJ 108) can be altered so that a bit data can be programmed into the MTJ 108. More specifically, a perpendicular spin current is flown along a ferromagnetic layer of the MTJ 108 to reset the orientation of the ferromagnetic layer to a neutral state, and a spin transfer current is applied to the MTJ 108 to switch the orientation of the ferromagnetic layer via spin transfer torque (STT). Utilizing both SOT and STT to program the orientation of the ferromagnetic layer can help switch the orientation of the ferromagnetic layer more quickly than utilizing SOT/STT alone. As such, the memory device 100 may be referred to as a STT-assisted spin-orbit torque MRAM (SOT-MRAM) device. During a read operation, the resistance state of an MTJ 108 can be sensed and the bit data stored in the MTJ 108 can be read out.

Each unit cell 102 further includes an access transistor AT. The access transistor AT in each unit cell 102 is coupled to the MTJ 108 and the bit line BL for the unit cell 102. The access transistors AT may be three-terminal devices. A gate terminal of each access transistor AT is coupled to one of the word lines WL. The access transistor AT in each unit cell 102 is coupled to the MTJ 108 through a first source/drain terminal and is coupled to one of the bit lines BL through a second source/drain terminal. A terminal of each MTJ 108 is coupled to an underlying portion of an SOT line 106, and the other terminal of each MTJ 108 is coupled to one of the bit lines BL through an access transistor AT.

The unit cells 102 are grouped into strings. Each string of unit cells 102 includes multiple MTJs 108, the access transistors AT for those MTJs 108, a shared SOT line 106, a string bit line SBL, a string source line SSL. The MTJs 108 of each string are directly coupled to the SOT line 106 of the string. Additionally, each string of the unit cells 102 includes a write transistor WT and (optionally) a source transistor ST. The write transistor WT and the source transistor ST may be coupled to portions of the SOT line 106 at opposite sides of the MTJs 108 on that SOT line 106, such that the MTJs 108 stand on a current path (e.g., the path for the previously described in-plane charge current) between the write transistor WT and the source transistor ST. Specifically, the MTJs 108 are spaced apart along the SOT line 106 between the write transistor WT and the source transistor ST. Accordingly, the MTJ 108 can be programmed by the in-plane charge current. The write transistors WT and the source transistors ST may be three-terminal devices. A gate terminal of each write transistor WT and source transistors ST may be coupled to the word line WL for the string. The write transistor WT of each string of unit cells 102 is coupled to the SOT line 106 for the string through a first source/drain terminal and is coupled to one of the string bit lines SBL through a second source/drain terminal. The source transistor ST of each string of unit cells 102 is coupled to the SOT line 106 for the string through a first source/drain terminal and is coupled to one of the string source lines SSL through a second source/drain terminal. In the illustrated embodiment, each string of unit cells 102 corresponds to a row of unit cells 102. In another embodiment (subsequently described), each row includes multiple strings of unit cells 102.

A word line driver 112 is coupled to the word lines WL. The word line driver 112 includes any acceptable circuit that is configured to control switching of the write transistors WT and the source transistors ST through the word lines WL. A current source 114 is coupled to the string source lines SSL and the string bit lines SBL. The current source 114 includes any acceptable circuit that is configured to provide a current (e.g., the previously described in-plane charge current) for programming the MTJs 108 as well as a read current for sensing the resistance states of the MTJs 108. The current source 114 is used in conjunction with the word line driver 112. A bit line driver 116 is coupled to the bit lines BL. The bit line driver 116 includes any acceptable circuit that is configured to sense the read current passing through the MTJs 108 (in order to identify the resistance states of the MTJs 108) and is further configured to provide a current (e.g., the previously described spin transfer current) for programming the MTJs 108.

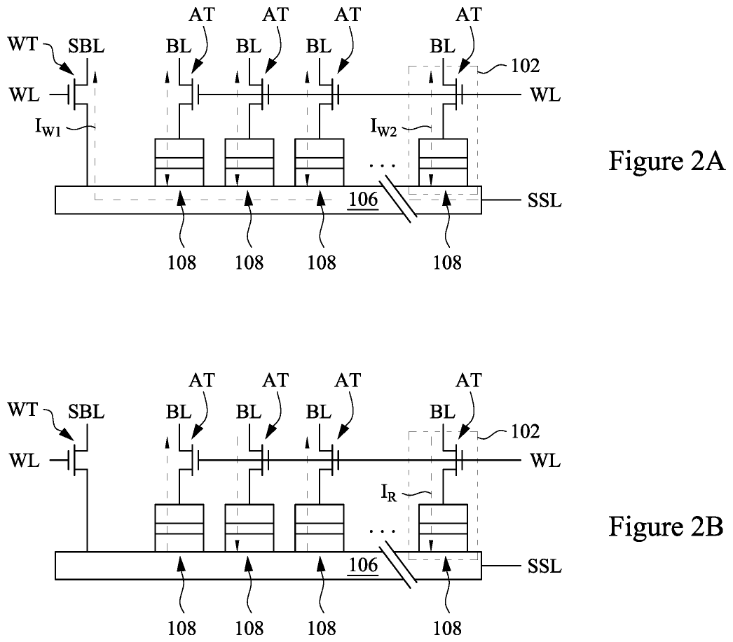

FIG. 2A illustrates a write path of unit cells 102 in the memory device 100, in accordance with some embodiments. A string of the unit cells 102 is illustrated. A programming operation is performed simultaneously for all unit cells 102 in a string. During a programming operation, the write transistor WT and the source transistor ST (see FIG. 1) for the selected string of unit cells 102 are both turned on and a first write current Iwi (e.g., the previously described in-plane charge current) flows through the SOT line 106 between the string bit line SBL and the string source line SSL. As a result of spin-orbit interaction, the first write current Iwi flowing through the SOT line 106 induces an SOT on the MTJs 108, which resets the MTJs 108. Additionally, the access transistors AT of the unit cells 102 are turned on and a second write current I_{W2} (e.g., the previously described spin transfer current) flows through each MTJ 108. As a result of spin transfer, the second write current I_{W2} flowing through each MTJ 108 induces a STT on the MTJ 108, which programs the MTJ 108. The write transistor WT, the source transistor ST, and the access transistors AT are turned on by setting the corresponding word line WL.

The first write current Iwi is provided by setting a voltage difference between the string source line SSL and the string bit line SBL with the current source 114 (see FIG. 1). The string bit line SBL may be set to a higher voltage than the string source line SSL. The voltage difference between the string source line SSL and the string bit line SBL may be set to induce a first write current Iwi in the SOT line 106 that is large enough to induce an SOT on the MTJs 108. In some embodiments, the first write current Iwi is larger than the overdrive current of the material of the SOT line 106, which allows for fast switching of the MTJs 108.

The second write current I_{W2} is provided on the bit lines BL by the bit line driver 116 (see FIG. 1). Each second write current I_{W2} is provided with a desired direction (e.g., polarity). The direction of the second write current I_{W2} provided to each MTJ 108 determines whether the MTJ 108 is programmed to a high-electrical resistance state or a low-electrical resistance state.

FIG. 2B illustrates a read path of unit cells 102 in the memory device 100, in accordance with some embodiments. A string of the unit cells 102 is illustrated. A read operation is performed simultaneously for all unit cells 102 in a string. During a read operation, the write transistor WT for the selected string of unit cells 102 is turned off and the source transistor ST (see FIG. 1) for the selected string of unit cells 102 is turned on. A voltage difference may be set between each of the bit lines BL and the string source line SSL, such that a read current IR flows through each MTJ 108. Each MTJ 108 may have different electrical resistances based on whether the ferromagnetic layers of the MTJ 108 have parallel magnetization orientations (e.g., indicating the MTJ 108 is in the low-resistance state) or anti-parallel magnetization orientations (e.g., indicating the MTJ 108 is in the high-resistance state). This variable resistance affects a value of a voltage drop across the MTJ 108. Therefore, the bit data (e.g., the resistance state) stored in the MTJ 108 can be read out.

In some embodiments, alternating read currents IR have opposite directions. For example, the read currents IR through a first subset (e.g., even ones) of the MTJs 108 in a string may have a first (e.g., positive) direction, while the read currents IR through a second subset (e.g., odd ones) of the MTJs 108 in the string may have a second (e.g., negative) direction. The direction of the read currents IR may be controlled by selection of the voltage difference between a bit line BL and the string source line SSL. When a bit line BL is set to a lesser voltage than the string source line SSL, the corresponding read current IR may have a first (e.g., positive) direction, and when a bit line BL is set to a greater voltage than the string source line SSL, the corresponding read current IR may have a second (e.g., negative) direction. The magnitude of the voltage drop across the corresponding MTJ 108 indicates whether the MTJ 108 is in the high-resistance state or the low-resistance state. Utilizing alternating read currents IR may help avoid read current accumulation in the SOT line 106.

In some embodiments, each read current IR has a same direction. For example, the read currents IR through each of the MTJs 108 in a string may have a first (e.g., positive) direction or a second (e.g., negative) direction. In such embodiments, voltage difference between the bit lines BL and the string source line SSL is large, so as to avoid read current accumulation in the SOT line 106.

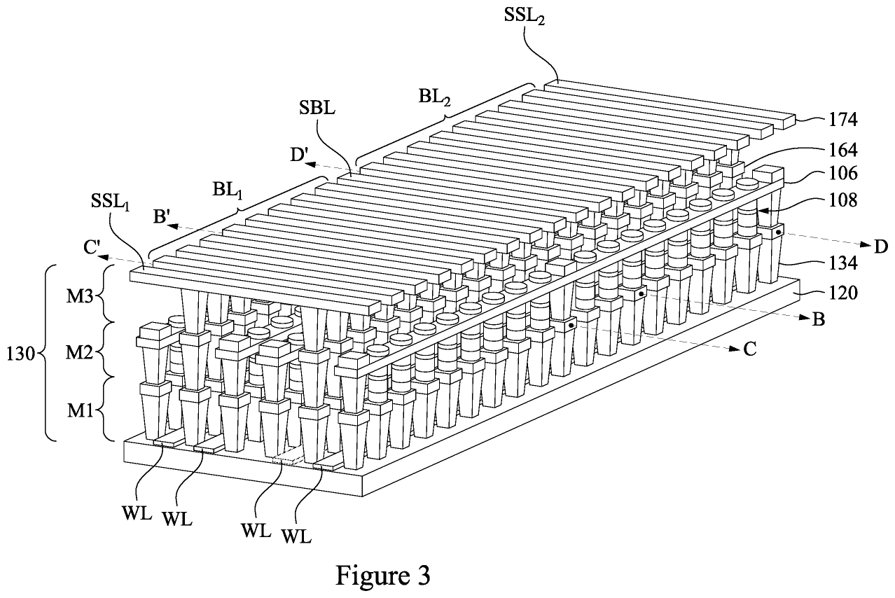

FIG. 3 is a three-dimensional view of the memory device 100, in accordance with some embodiments. As previously noted, each string of unit cells 102 (see FIG. 1) has MTJs 108 that share an SOT line 106. In this embodiment, the SOT lines 106 are formed above the MTJs 108. The memory device 100 may have a mirror design, in which multiple strings of unit cells 102 are disposed along a row. For example, in the illustrated mirror design, a first set of bit lines BL₁ are disposed between a first string bit line SBL₁ and a shared string source line SSL, while a second set of bit lines BL₂ are disposed between a second string bit line SBL₂ and the shared string source line SSL. Utilizing a mirror design may help reduce voltage drops across the SOT lines 106. The memory device 100 includes an interconnect structure 130 over a semiconductor substrate 120.

The semiconductor substrate 120 may be silicon, doped or undoped, or an active layer of a semiconductor-on-insulator (SOI) substrate. The semiconductor substrate 120 may include other semiconductor materials, such as germanium; a compound semiconductor including silicon carbide, gallium arsenic, gallium phosphide, gallium nitride, indium phosphide, indium arsenide, and/or indium antimonide; an alloy semiconductor including SiGe, GaAsP, AlInAs, AlGaAs, GaInAs, GaInP, and/or GaInAsP; or combinations thereof. Other substrates, such as multilayered or gradient substrates, may also be used. Devices are at the active surface of the semiconductor substrate 120. The devices may be active devices or passive devices. For example, the devices may be transistors, diodes, capacitors, resistors, or the like. The devices include the write transistor WT, source transistor ST, and access transistors AT (see FIG. 1) of the memory device 100. In some embodiments, the devices include gate structures and source/drain regions, with the gate structures acting as the word lines WL of the memory device 100.

The interconnect structure 130 interconnects the devices of the semiconductor substrate 120 to form the memory device 100. The interconnect structure 130 includes multiple metallization layers M1-M3. Although three metallization layers M1-M3 are illustrated, it should be appreciated that more or less metallization layers may be included. Each of the metallization layers M1-M3 includes metallization patterns in dielectric layers (subsequently described). The metallization patterns are electrically coupled to the devices of the semiconductor substrate 120, the MTJs 108, and the SOT lines 106.

The MTJs 108 and the SOT lines 106 are included in the interconnect structure 130. The MTJs 108 can be in any of the metallization layers M1-M3, and are illustrated as being in a second metallization layer M2. The MTJs 108 and the SOT lines 106 are electrically connected to the devices of the semiconductor substrate 120. As will be subsequently described in greater detail, the process utilized to form the memory device 100 allows shared SOT lines 106 to be formed directly on corresponding MTJs 108.

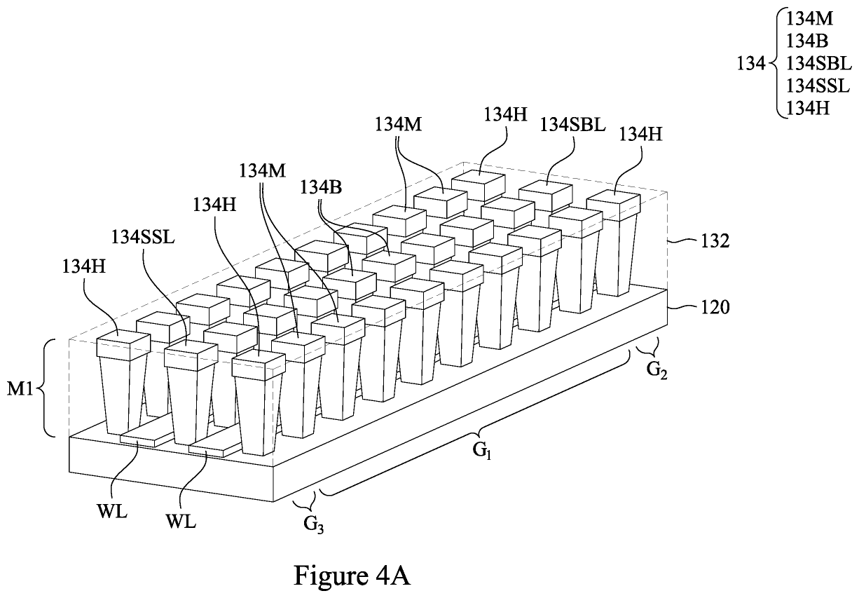

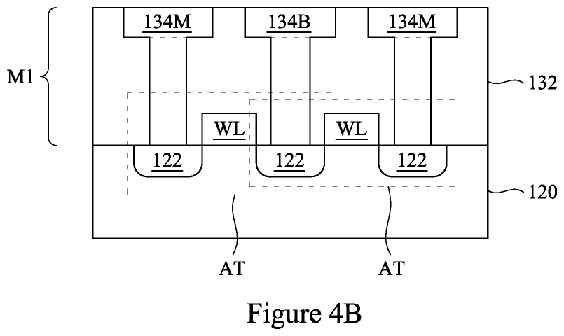

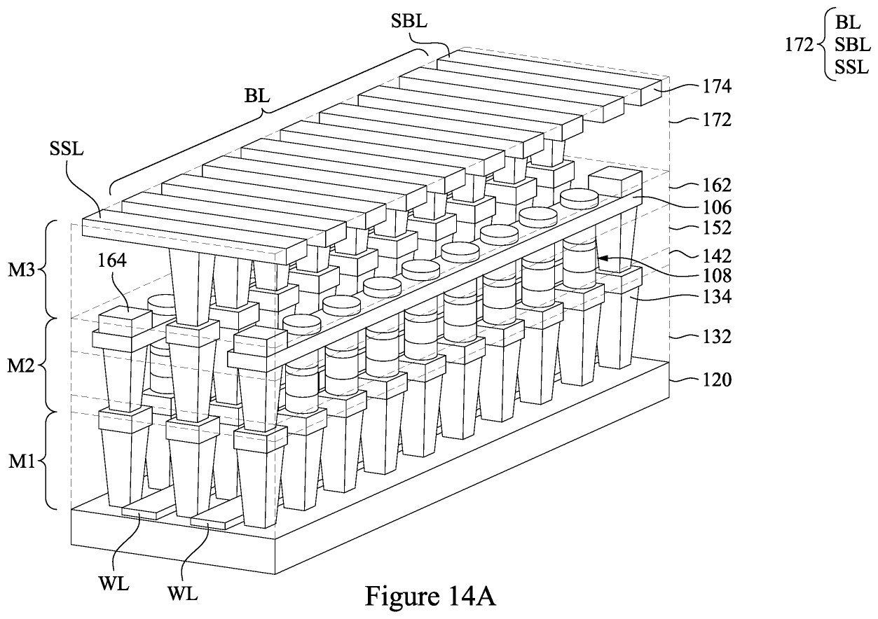

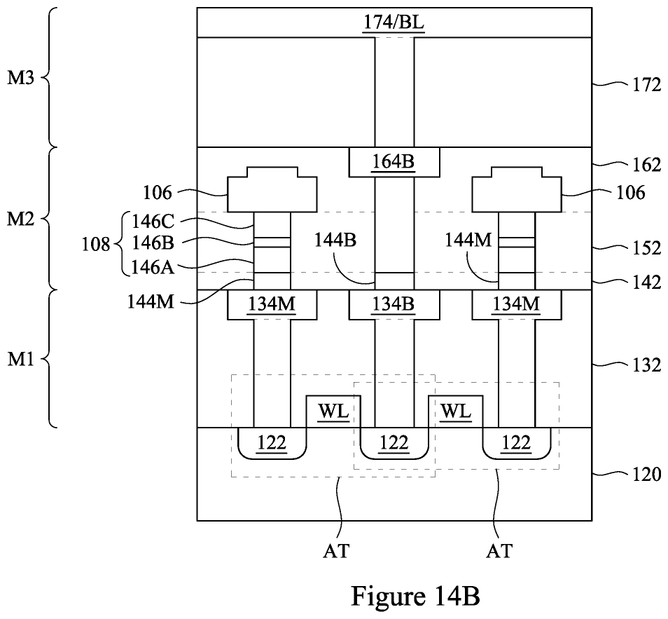

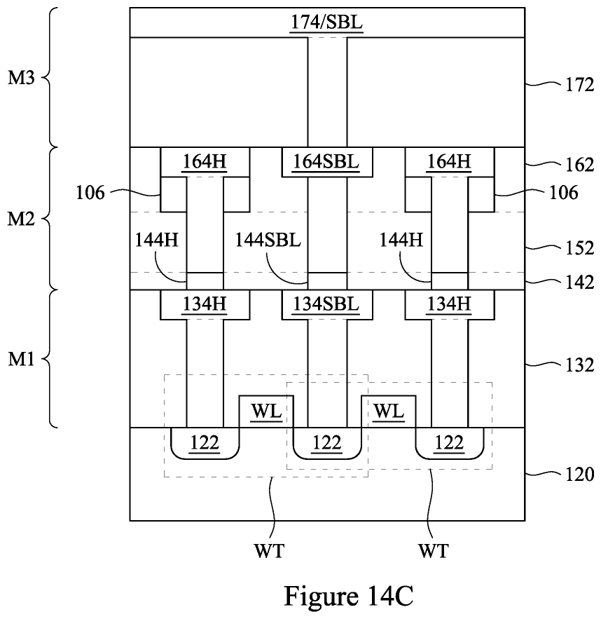

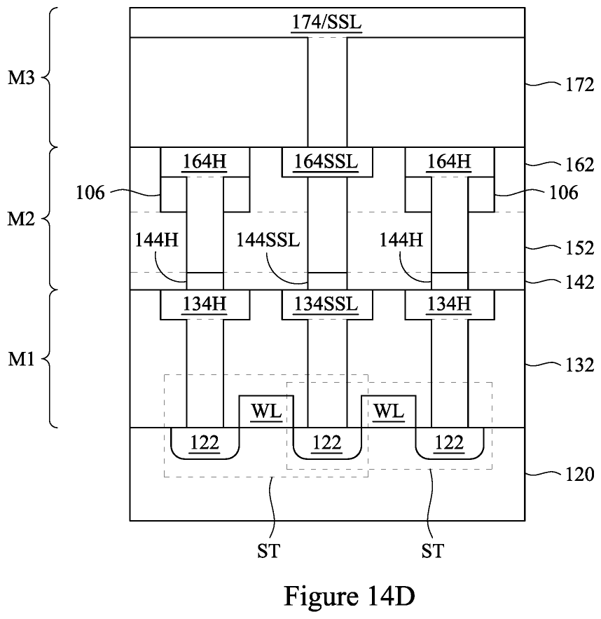

FIGS. 4A-14D are view of intermediate stages in the manufacturing of the memory device 100 of FIG. 3, in accordance with some embodiments. Specifically, the manufacturing of the interconnect structure 130 (including the MTJs 108 and the SOT lines 106) of FIG. 3 is shown. FIGS. 4A, 5A, 6A, 7A, 8A, 9A, 10A, 11A, 12A, 13A, and 14A are three-dimensional views of a portion of the memory device 100 of FIG. 3 (specifically, one side of the mirrored structure). FIGS. 4B, 5B, 6B, 7B, 8B, 9B, 10B, 11B, 12B, 13B, and 14B are cross-sectional views shown along reference cross-section B-B′ in FIG. 3, except only two SOT lines 106 are shown. FIG. 14C is a cross-sectional view shown along reference cross-section C-C′ in FIG. 3, except only two SOT lines 106 are shown. FIG. 14D is a cross-sectional view shown along reference cross-section D-D′ in FIG. 3, except only two SOT lines 106 are shown.

In FIGS. 4A-4B, a semiconductor substrate 120 is received or formed. The semiconductor substrate 120 includes devices (previously described), which may be formed using any acceptable front end of line (FEOL) process. The devices include the write transistor WT, source transistor ST, and access transistors AT (see FIG. 1).

A first metallization layer M1 of the interconnect structure 130 is formed over the semiconductor substrate 120. The first metallization layer M1 may be formed using any acceptable back end of line (BEOL) process. For example, an IMD 132 may be formed over the semiconductor substrate 120, and a metallization pattern 134 may be formed in the IMD 132. The IMD 132 may be formed of any suitable dielectric material, such as silicon oxide, phosphosilicate glass (PSG), borosilicate glass (BSG), boron-doped phosphosilicate glass (BPSG), or the like, which may be formed by any acceptable deposition process such as chemical vapor deposition (CVD), physical vapor deposition (PVD), or the like. The metallization pattern 134 is formed in the IMD 132. The metallization pattern 134 may be formed of any suitable conductive material, such as copper, aluminum, tungsten, silver, and combinations thereof, or the like. The metallization pattern 134 may formed by a damascene process, such as a single damascene process, a dual damascene process, or the like. After the damascene process, the top surfaces of the metallization pattern 134 are substantially coplanar (within process variations) with the top surface of the IMD 132.

The metallization pattern 134 includes metal pads and metal vias that are electrically connected to the devices of the semiconductor substrate 120. A subset of the metal pads/vias 134M will be subsequently utilized for connecting overlying MTJs to the access transistors AT (see FIG. 14B). A subset of the metal pads/vias 134B will be subsequently utilized for connecting overlying bit lines BL to the access transistors AT (see FIG. 14B). A subset of the metal pads/vias 134SBL will be subsequently utilized for connecting overlying string bit lines SBL to the write transistors WT (see FIG. 14C). A subset of the metal pads/vias 134SSL will be subsequently utilized for connecting overlying string source lines SSL to the source transistors ST (see FIG. 14D). A subset of the metal pads/vias 134H will be subsequently utilized for connecting overlying SOT lines to the write transistors WT (see FIG. 14C) and source transistors ST (see FIG. 14D).

The metal vias 134M/134B are arranged in rows, with each row of metal vias 134B between two rows of the metal vias 134M. A group G₁ of the metal vias 134M/134B is between a group G2 of the metal vias 134SBL/134H and a group G3 of the metal vias 134SSL/134H. Forming the metal vias with such a layout allows the features for each string of unit cells 102 (see FIG. 1) to be interconnected in a small area.

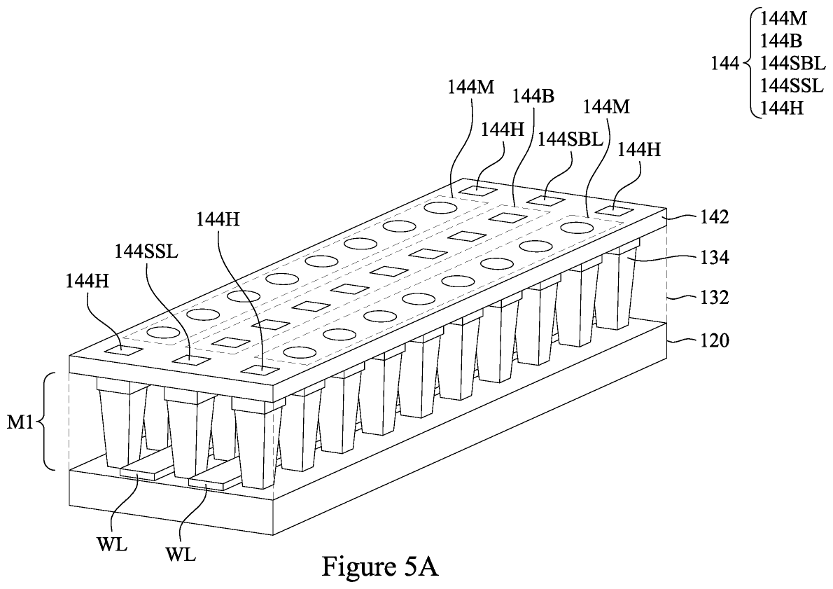

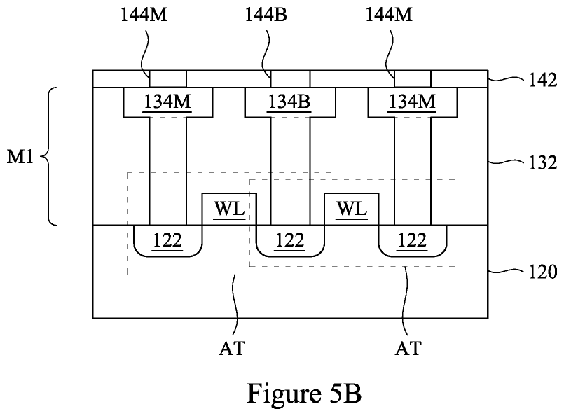

In FIGS. 5A-5B, an IMD 142 is formed over the first metallization layer M1, and a metallization pattern 144 is formed in the IMD 142. The IMD 142 may be formed of any suitable dielectric material, such as silicon oxide, phosphosilicate glass (PSG), borosilicate glass (BSG), boron-doped phosphosilicate glass (BPSG), or the like, which may be formed by any acceptable deposition process such as chemical vapor deposition (CVD), physical vapor deposition (PVD), or the like. The metallization pattern 144 is formed in the IMD 142. The metallization pattern 144 may be formed of any suitable conductive material, such as copper, aluminum, tungsten, silver, and combinations thereof, or the like. The metallization pattern 144 may formed by a damascene process, such as a single damascene process, a dual damascene process, or the like. After the damascene process, the top surfaces of the metallization pattern 144 are substantially coplanar (within process variations) with the top surface of the IMD 142.

The metallization pattern 144 includes metal vias that are electrically connected to the metallization pattern 134. A subset of the metal vias 144M are connected to the metal pads/vias 134M. MTJs will be subsequently formed on the metal vias 144M, which act as bottom electrodes for the subsequently formed MTJs. A subset of the metal vias 144B are connected to the metal pads/vias 134B. A subset of the metal vias 144SBL are connected to the metal pads/vias 134SBL. A subset of the metal vias 144SSL are connected to the metal pads/vias 134SSL. A subset of the metal vias 144H are connected to the metal pads/vias 134H.

The metal vias 144B/144SBL/144SSL/144H may (or may not) have a different shape than the metal vias 144M in a top-down view. In some embodiments, the metal vias 144B/144SBL/144SSL/144H have a first shape (e.g., a rectangular shape) in the top-down view, and the metal vias 144M have a second shape (e.g., a circular shape) in the top-down view.

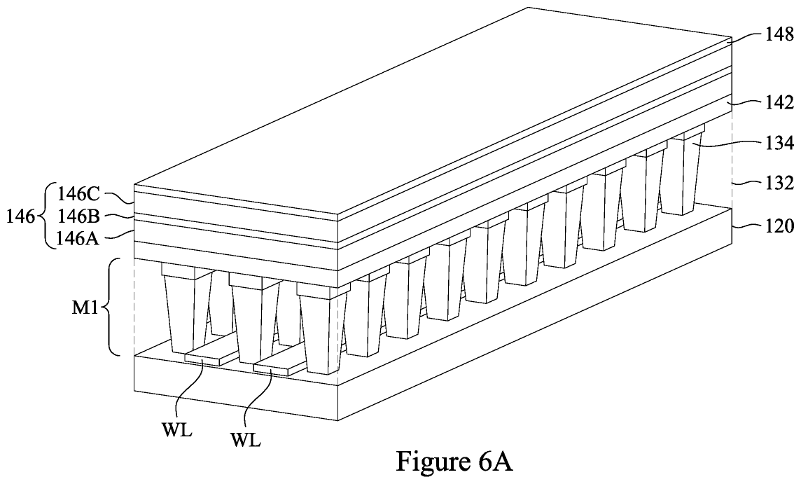

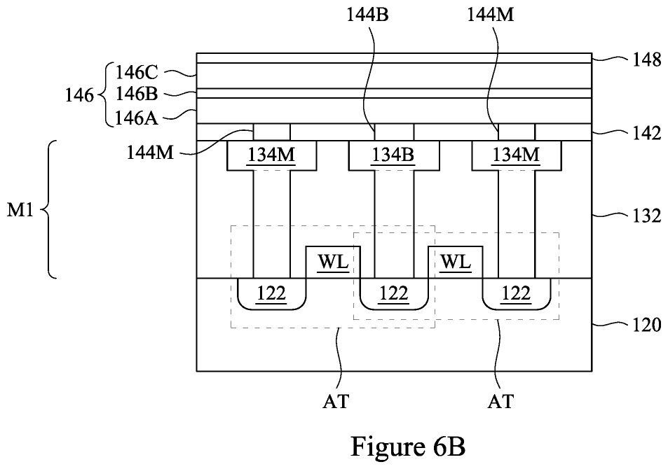

In FIGS. 6A-6B, an MTJ film stack 146 is formed on the IMD 142 and the metallization pattern 144. The MTJ film stack 146 is a multilayer that includes a fixed layer 146A, a barrier layer 146B over the fixed layer 146A, and a free layer 146C over the barrier layer 146B. Each layer of the MTJ film stack 146 may be deposited using one or more deposition methods such as, CVD, PVD, ALD, a combination thereof, or the like.

The fixed layer 146A may be formed of a ferromagnetic material with a greater coercivity field than the free layer 146C, such as cobalt iron (CoFe), cobalt iron boron (CoFeB), a combination thereof, or the like. In some embodiments, the fixed layer 146A has a synthetic ferromagnetic (SFM) structure, in which the coupling between magnetic layers is ferromagnetic coupling. In some embodiments, the fixed layer 146A has a synthetic antiferromagnetic (SAF) structure including a plurality of magnetic metal layers separated by a plurality of non-magnetic spacer layers. The magnetic metal layers may be formed of Co, Fe, Ni, or the like. The non-magnetic spacer layers may be formed of Cu, Ru, Ir, Pt, W, Ta, Mg, or the like. For example, the fixed layer 146A may have a Co layer and repeated (Pt/Co)ₓ layers over the Co layer, with x representing a repeating number that can be any integer greater than or equal to 1.

The barrier layer 146B may be formed of a dielectric material, such as MgO, AlO, AlN, a combination thereof, or the like. The barrier layer 146B is thinner than the other layers of the MTJ film stack 146. The barrier layer 146B may have a thickness in the range of 1 nm to 10 nm.

The free layer 146C may be formed of a suitable ferromagnetic material such as CoFe, NiFe, CoFeB, CoFeBW, a combination thereof, or the like. The free layer 146C may also adopt a synthetic ferromagnetic (SFM) structure, with the thickness of the non-magnetic spacer layers adjusted to achieve ferromagnetic coupling between the separated magnetic metals, e.g., causing the magnetic moment to be coupled in the same direction. The magnetic moment of the free layer 146C is programmable, and the resistances of the resulting MTJs is accordingly programmable. Specifically, the resistances of the resulting MTJs can be changed between a high-electrical resistance state and a low-electrical resistance state based on the programmed magnetic moment of the free layer 146C, relative the fixed layer 146A.

Additionally, an electrode seed layer 148 is formed over the MTJ film stack 146. The electrode seed layer 148 is formed of a suitable conductive material for subsequently seeding the deposition of a conductive material with high spin Hall conductivity (subsequently described). In some embodiments, the electrode seed layer 148 is formed of the same material as the subsequently formed conductive material.

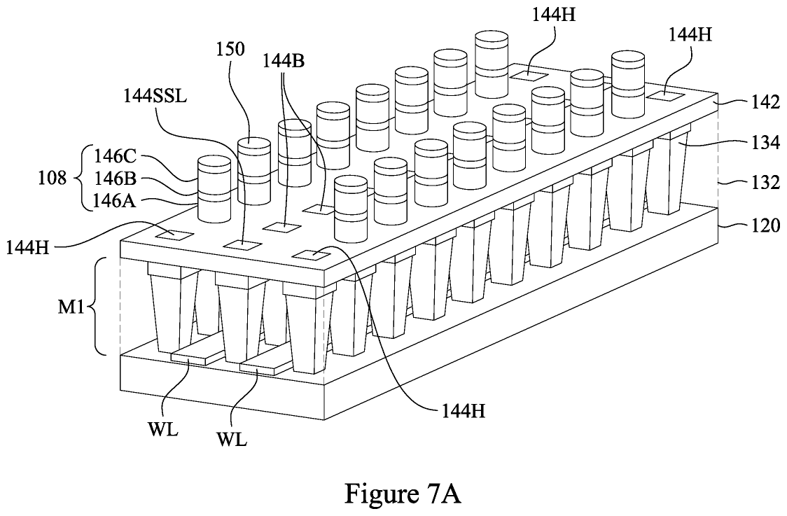

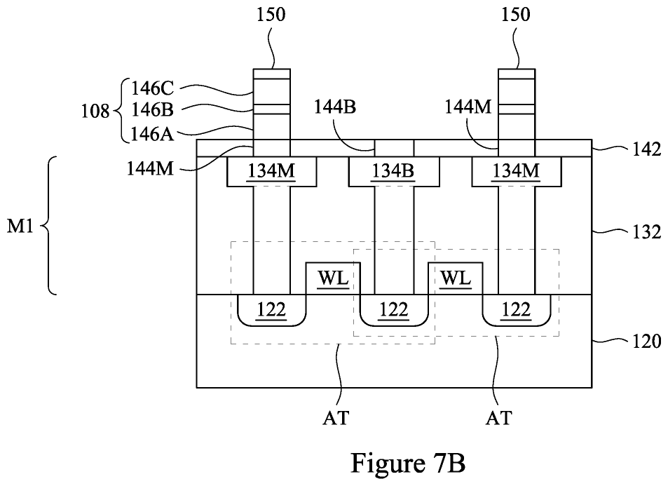

In FIGS. 7A-7B, the electrode seed layer 148 and the MTJ film stack 146 are patterned to form, respectively, electrode seed structures 150 and MTJs 108. The etching method may include a plasma etching method, such as ion beam etching (IBE). The etching may be implemented using glow discharge plasma (GDP), capacitive coupled plasma (CCP), inductively coupled plasma (ICP), or the like. For example, when the etching method is an IBE process, it can be performed with etchants such as methanol (CH₃OH), ammonia (NH₃), or the like. Each MTJ 108 includes a patterned portion of the MTJ film stack 146 (including patterned portions of the fixed layer 146A, the barrier layer 146B, and the free layer 146C). Each electrode seed structure 150 is formed on a respective MTJ 108, and includes a patterned portion of the electrode seed layer 148.

The MTJs 108 (and electrode seed structures 150) are formed on the metal vias 144M (see also FIG. 5A). The metal vias 144B/144SBL/144SSL/144H are exposed by the patterning of the electrode seed layer 148 and the MTJ film stack 146.

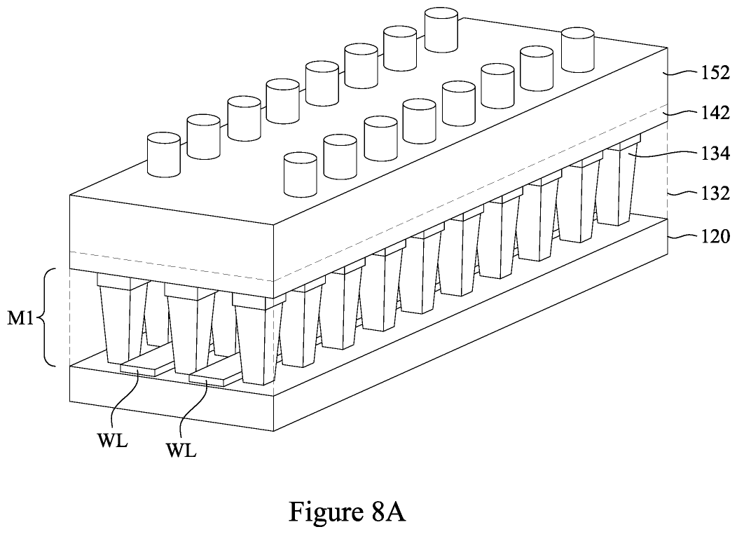

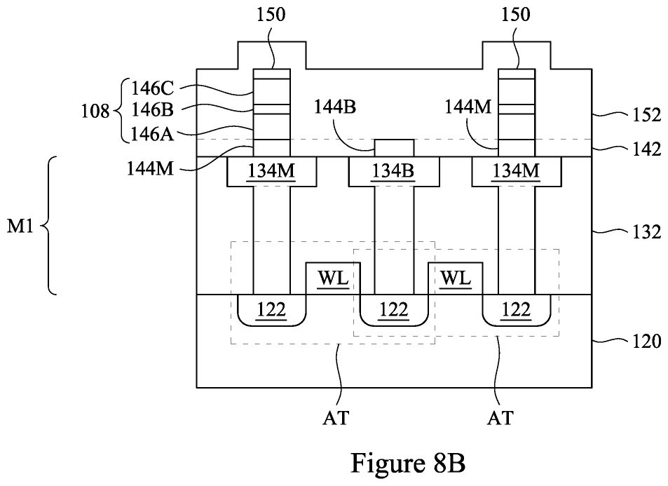

In FIGS. 8A-8B, an IMD 152 is formed on the electrode seed structures 150, the MTJs 108, and the IMD 142. The IMD 152 may be formed of any suitable dielectric material, such as silicon oxide, phosphosilicate glass (PSG), borosilicate glass (BSG), boron-doped phosphosilicate glass (BPSG), or the like, which may be formed by any acceptable deposition process such as chemical vapor deposition (CVD), physical vapor deposition (PVD), or the like. The IMD 152 is formed to a large enough thickness that the electrode seed structures 150 are buried.

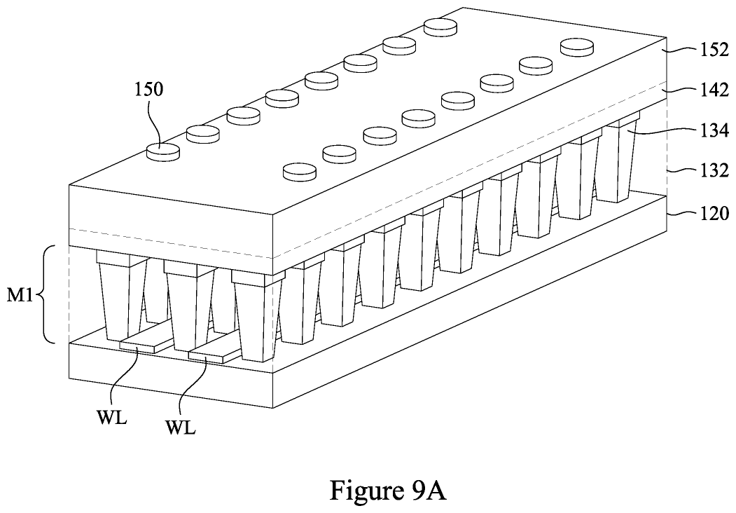

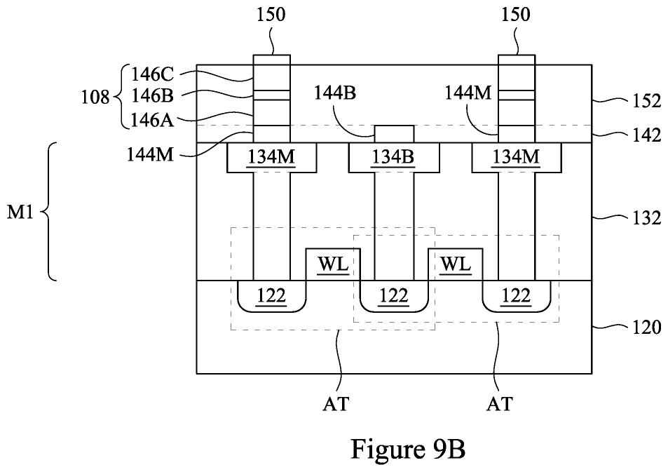

In FIGS. 9A-9B, the IMD 152 is recessed to expose the electrode seed structures 150. The IMD 152 may be recessed by any acceptable etching process that selectively etches the material of the IMD 152 at a faster rate than the material of the electrode seed structures 150. The etching may be anisotropic.

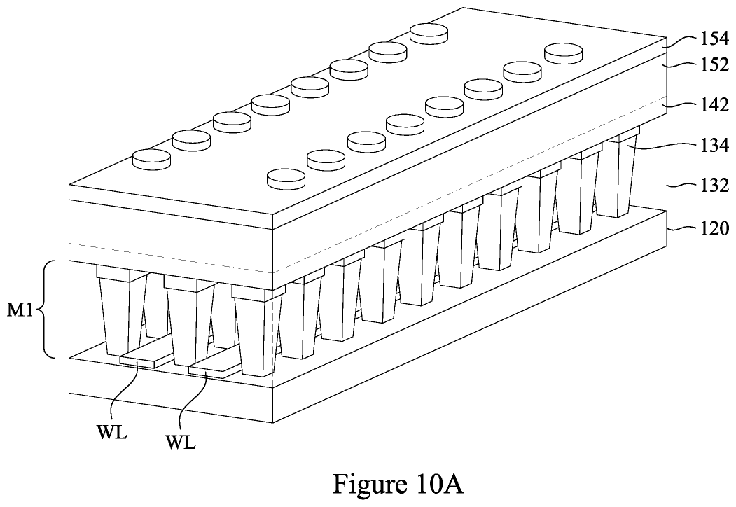

In FIGS. 10A-10B, an electrode layer 154 is formed on the IMD 152 and the exposed portions of the electrode seed structures 150. The electrode layer 154 is formed of a conductive material with high spin Hall conductivity, which may be deposited on the electrode seed structures 150. For example, the electrode layer 154 may be formed of a metal alloy including at least one heavy metal element and at least one light transition metal element. The heavy metal element may be a metal element with valence electron(s) filling in 5d orbitals, such as platinum (Pt), palladium (Pd), tungsten (W), or the like. The light transition metal element may be a metal element with valence electron(s) partially filling in 3d orbitals, such as scandium (Sc), titanium (Ti), vanadium (V), chromium (Cr), manganese (Mn), iron (Fe), cobalt (Co), nickel (Ni), copper (Cu), or the like. As an example, the electrode layer 154 may be formed of a platinum-chromium alloy (e.g., PtₓCr₁₋ₓ, wherein x is in the range of 0.5 to 0.8). The material of the electrode layer 154 may be formed by a deposition process such as sputtering, in which a sputtering target including the heavy metal element and another sputtering target including the light transition metal element are utilized. The deposited material(s) may be thermally treated, such as by a suitable annealing process, to cause the heavy metal element and the light transition metal element to inter-diffuse and thereby form the electrode layer 154.

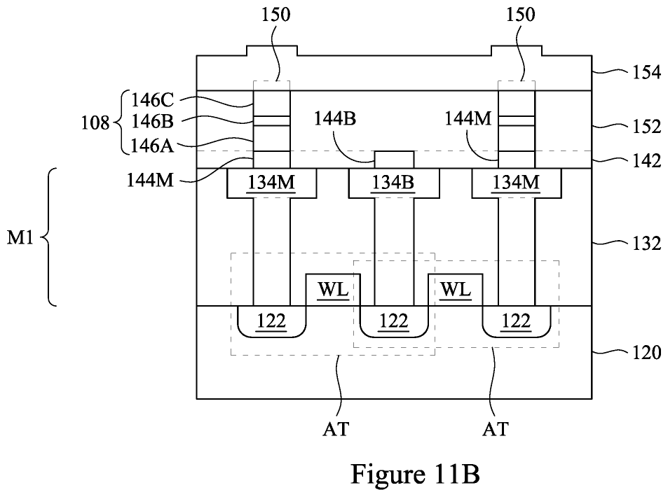

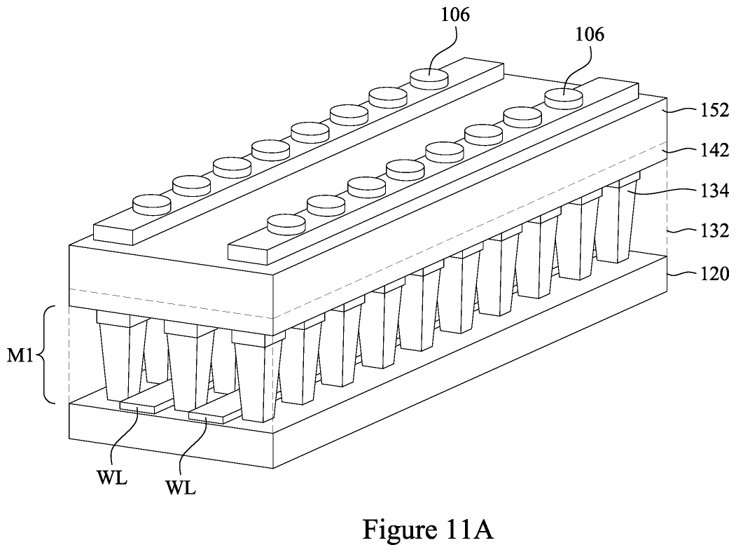

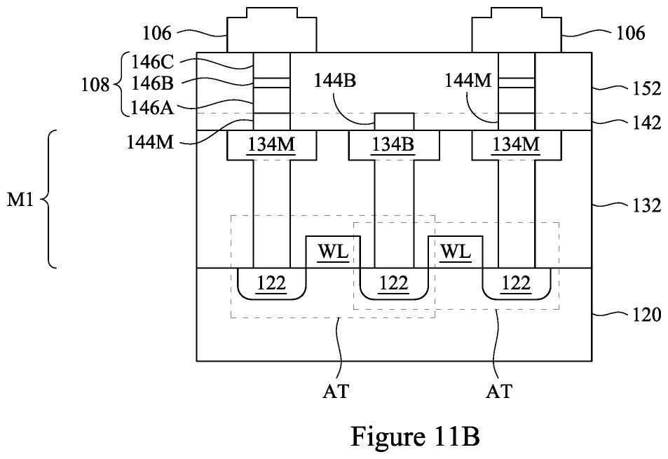

In FIGS. 11A-11B, the electrode layer 154 is patterned to form SOT lines 106. Each SOT line 106 is on a row of the MTJs 108, and acts as a top electrode for the underlying MTJs 108. The electrode layer 154 may be patterned by acceptable photolithography and etching processes. The etching process may selectively etch the material of the electrode layer 154 at a faster rate than the material of the IMD 152. The etching may be anisotropic. The SOT lines 106 include the remaining portions of the electrode layer 154 and the electrode seed structures 150.

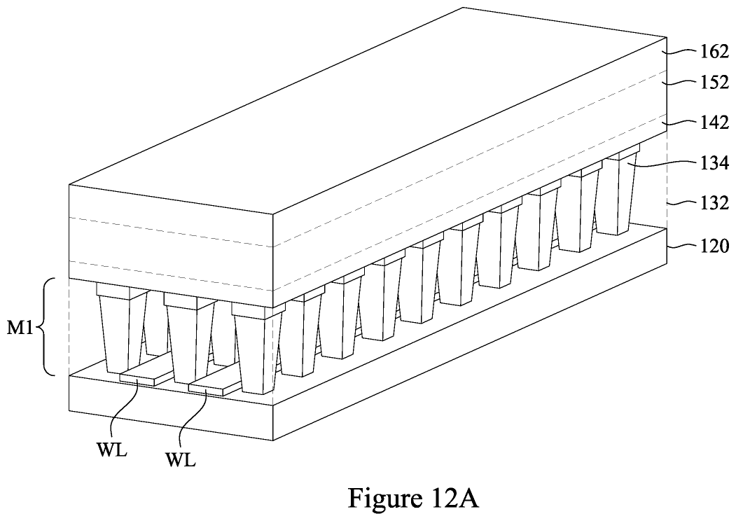

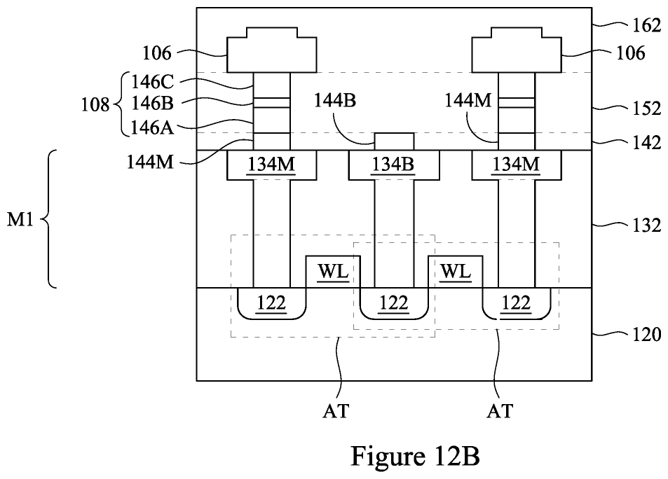

In FIGS. 12A-12B, an IMD 162 is formed on the SOT lines 106 and the IMD 152. The IMD 162 may be formed of any suitable dielectric material, such as silicon oxide, phosphosilicate glass (PSG), borosilicate glass (BSG), boron-doped phosphosilicate glass (BPSG), or the like, which may be formed by any acceptable deposition process such as chemical vapor deposition (CVD), physical vapor deposition (PVD), or the like. The IMD 162 is formed to a large enough thickness that the SOT line 106 are buried. Optionally, a planarization process, such as a CMP, may be performed on the IMD 162 after the material of the IMD 162 is deposited.

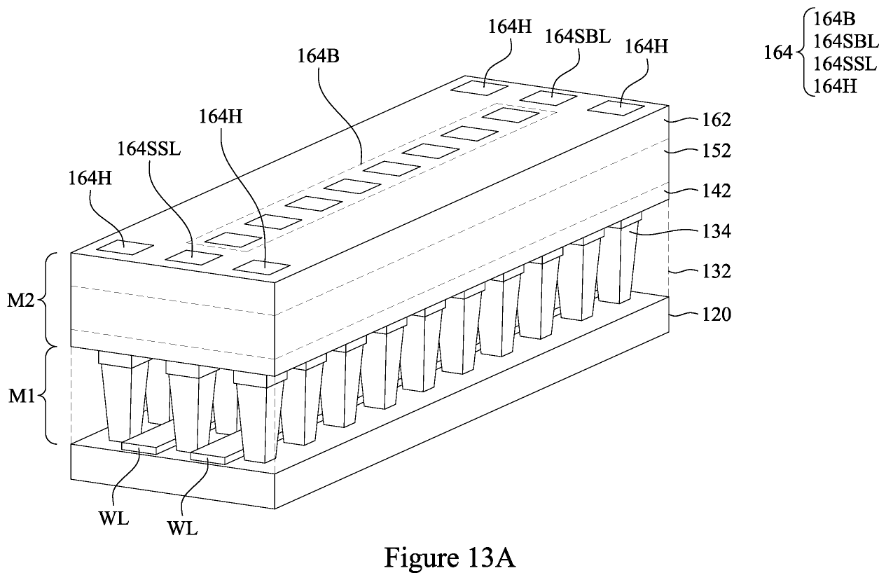

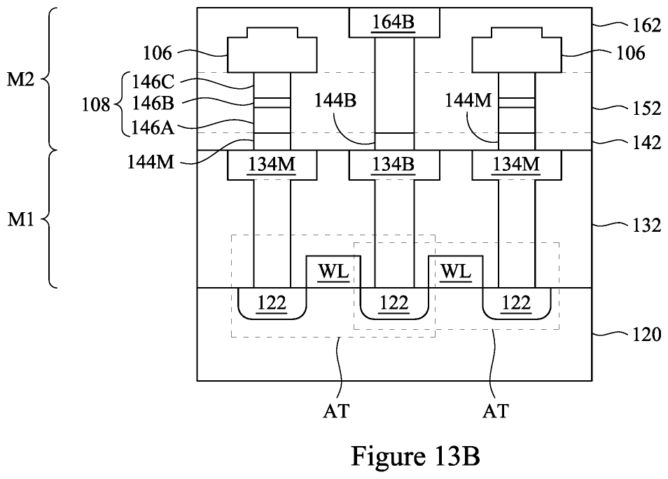

In FIGS. 13A-13B, a metallization pattern 164 is formed in the IMD 162, thereby completing formation of a second metallization layer M2 of the interconnect structure 130. The metallization pattern 164 may be formed of any suitable conductive material, such as copper, aluminum, tungsten, silver, and combinations thereof, or the like. The metallization pattern 164 may formed by a damascene process, such as a single damascene process, a dual damascene process, or the like. After the damascene process, the top surfaces of the metallization pattern 164 are substantially coplanar (within process variations) with the top surface of the IMD 162.

The metallization pattern 164 includes metal pads and metal vias that are electrically connected to the metallization pattern 144 (see FIG. 7A) and the SOT lines 106. A subset of the metal pads/vias 164B are connected to the metal vias 144B. A subset of the metal pads/vias 164SBL are connected to the metal vias 144SBL. A subset of the metal pads/vias 164SSL are connected to the metal vias 144SSL. A subset of the metal pads/vias 164H connect the SOT lines 106 to the metal vias 144H. Specifically, the metal pads/vias 164H include metal pads on the SOT lines 106 and further include metal vias that extend through the SOT lines 106 to connect the metal pads and the SOT lines 106 to the metal vias 144H.

In FIGS. 14A-14D, an third metallization layer M3 of the interconnect structure 130 is formed over the second metallization layer M2. The third metallization layer M3 may be formed using any acceptable back end of line (BEOL) process. For example, an IMD 172 may be formed over the IMD 162, and a metallization pattern 174 may be formed in the IMD 172. The IMD 172 may be formed of any suitable dielectric material, such as silicon oxide, phosphosilicate glass (PSG), borosilicate glass (BSG), boron-doped phosphosilicate glass (BPSG), or the like, which may be formed by any acceptable deposition process such as chemical vapor deposition (CVD), physical vapor deposition (PVD), or the like. The metallization pattern 174 is formed in the IMD 172. The metallization pattern 174 may be formed of any suitable conductive material, such as copper, aluminum, tungsten, silver, and combinations thereof, or the like. The metallization pattern 174 may formed by a damascene process, such as a single damascene process, a dual damascene process, or the like. After the damascene process, the top surfaces of the metallization pattern 174 are substantially coplanar (within process variations) with the top surface of the IMD 172.

The metallization pattern 174 includes metal lines and metal vias that are electrically connected to the metallization pattern 164 (see FIG. 13A). The metal lines include the bit lines BL, the string bit lines SBL, and the string source lines SSL, each of which are substantially perpendicular to the word lines WL (e.g., to the gate structures of the devices of the semiconductor substrate 120). The bit lines BL are connected to the metal pads/vias 164B. The string bit lines SBL are connected to the metal pads/vias 164SBL. The string source lines SSL are connected to the metal pads/vias 164SSL. The metallization pattern 174 may also include word lines (not separately illustrated) that are connected to the word lines WL (e.g., to the gate structures of the devices of the semiconductor substrate 120).

The metallization patterns 134, 144, 164, 174 interconnect the MTJs 108, the SOT lines 106, and the devices of the semiconductor substrate 120 to form the memory device 100. Therefore, an integrated circuit implementing the memory device 100 of FIG. 1 is formed. As shown by FIG. 14B, the metal pads/vias 134B, the metal vias 144B, and the metal pads/vias 164B collectively connect the bit lines BL to source/drain regions 122 of the access transistors AT. As also shown by FIG. 14B, the metal pads/vias 134M and the metal vias 144M collectively connect the MTJs 108 to source/drain regions 122 of the access transistors AT. As shown by FIG. 14C, the metal pads/vias 134SBL, the metal vias 144SBL, and the metal pads/vias 164SBL collectively connect the string bit lines SBL to source/drain regions 122 of the write transistors WT. As shown by FIG. 14D, the metal pads/vias 134SSL, the metal vias 144SSL, and the metal pads/vias 164SSL collectively connect the string source lines SSL to source/drain regions 122 of the source transistors ST. As shown by FIGS. 14C and 14D, the metal pads/vias 134H, the metal vias 144H, and the metal pads/vias 164H collectively connect the SOT lines 106 to source/drain regions 122 of the write transistors WT and the source transistors ST.

Various metal pads/vias in the metallization layers M1-M3 may be aligned such that their centers are disposed along a same vertical axis. In some embodiments, the bit lines BL are connected to the source/drain regions 122 of the access transistors AT by an aligned set of metal pads/vias. In some embodiments, the MTJs 108 are connected to the source/drain regions 122 of the access transistors AT by an aligned set of metal pads/vias. In some embodiments, the string bit lines SBL are connected to the source/drain regions 122 of the write transistors WT by an aligned set of metal pads/vias. In some embodiments, the string source lines SSL are connected to the source/drain regions 122 of the source transistors ST by an aligned set of metal pads/vias. In some embodiments, the SOT lines 106 are connected to the source/drain regions 122 of the write transistors WT and the source transistors ST by an aligned set of metal pads/vias.

Embodiments may achieve advantages. Forming the SOT lines 106 by initially forming the electrode seed structures 150 on the MTJs 108 and then subsequently forming/patterning the electrode layer 154 on the electrode seed structures 150 may be advantageous. Specifically, the electrode seed structures 150 may be exposed through the IMD 152 with a recessing process, instead of utilizing a CMP process to expose the MTJs 108 through the IMD 152. Risk of damage to the MTJs 108 may thus be reduced even when the resulting SOT lines 106 are disposed directly on the MTJs 108. No intervening layers are between the SOT lines 106 and the MTJs 108, thereby reducing the contact resistance of the MTJs 108. Additionally, forming the metallization patterns 134, 144, 164, 174 with the previously described layout allows the memory device 100 to be formed to a greater density. Specifically, each string of unit cells 102 (see FIG. 1) only utilizes one write transistor WT and one SOT line 106, as compared to other STT-assisted SOT-MRAM devices where each MTJ 108 in a string has its own SOT line and its own write transistor. Write transistors may be large, and so reducing the quantity of write transistors in the memory device 100 allows for an increase in density. In some embodiments, each unit cell 102 occupies as little as 6 times the minimum feature size of the memory device 100.

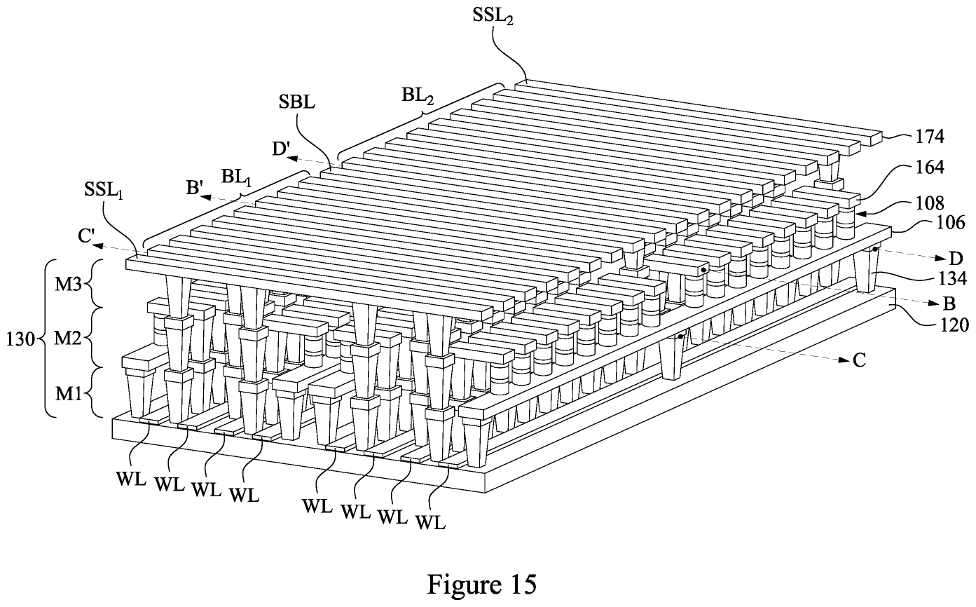

FIG. 15 is a three-dimensional view of a memory device 100, in accordance with some embodiments. As previously noted, each string of unit cells 102 (see FIG. 1) has MTJs 108 that share an SOT line 106. In this embodiment, the SOT line 106 are formed below the MTJs 108. The memory device 100 may have a mirror design, in which multiple strings of unit cells 102 are disposed along a row. For example, in the illustrated mirror design, a first set of bit lines BL₁ are disposed between a first string bit line SBL₁ and a shared string source line SSL, while a second set of bit lines BL₂ are disposed between a second string bit line SBL₂ and the shared string source line SSL. Similar to the embodiment of FIG. 3, the memory device 100 includes an interconnect structure 130 over a semiconductor substrate 120.

The MTJs 108 and the SOT lines 106 are included in the interconnect structure 130. The MTJs 108 can be in any of the metallization layers M1-M3, and are illustrated as being in a second metallization layer M2. The MTJs 108 and the SOT lines 106 are electrically connected to the devices of the semiconductor substrate 120. As will be subsequently described in greater detail, the process utilized to form the memory device 100 allows MTJs 108 to be formed directly on corresponding shared SOT lines 106. Additionally, in this embodiment, the structure of the MTJs 108 may be reversed. Accordingly, the free layer 146C may be the bottom layer of the MTJ film stack 146, and the fixed layer 146A may be the top layer of the MTJ film stack 146.

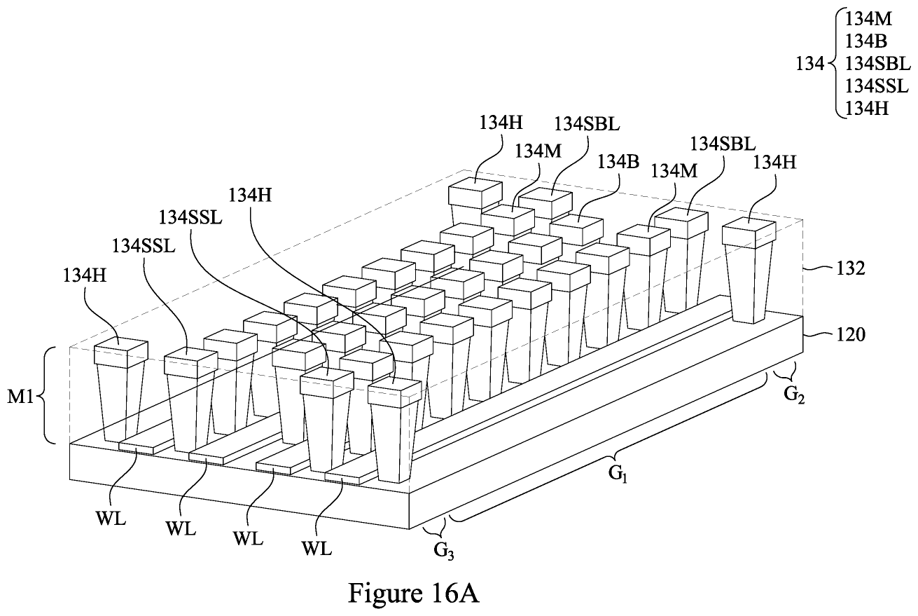

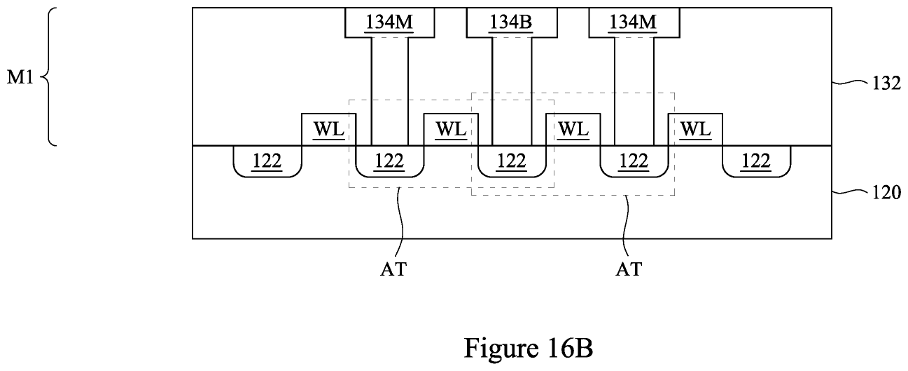

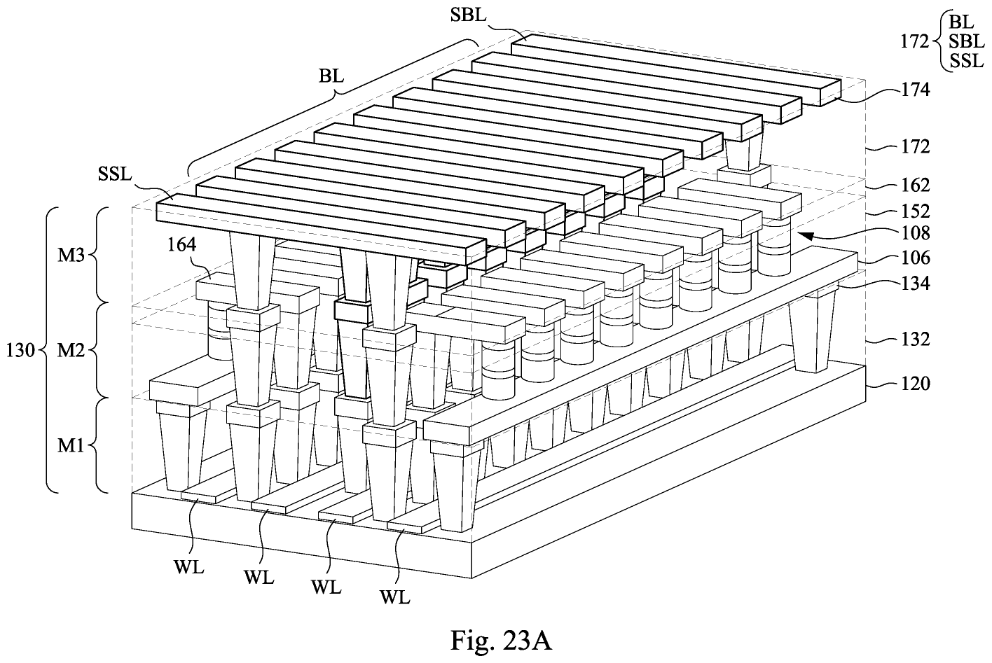

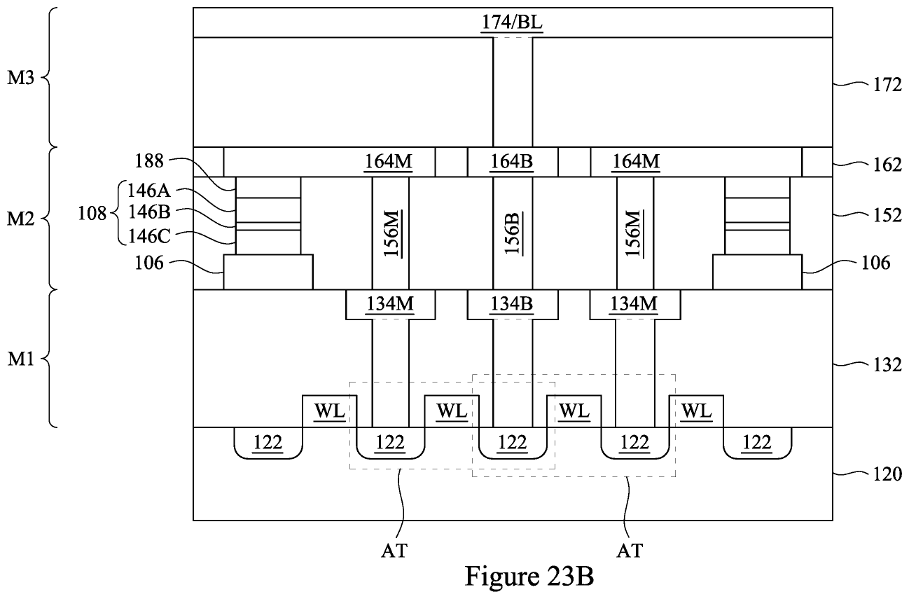

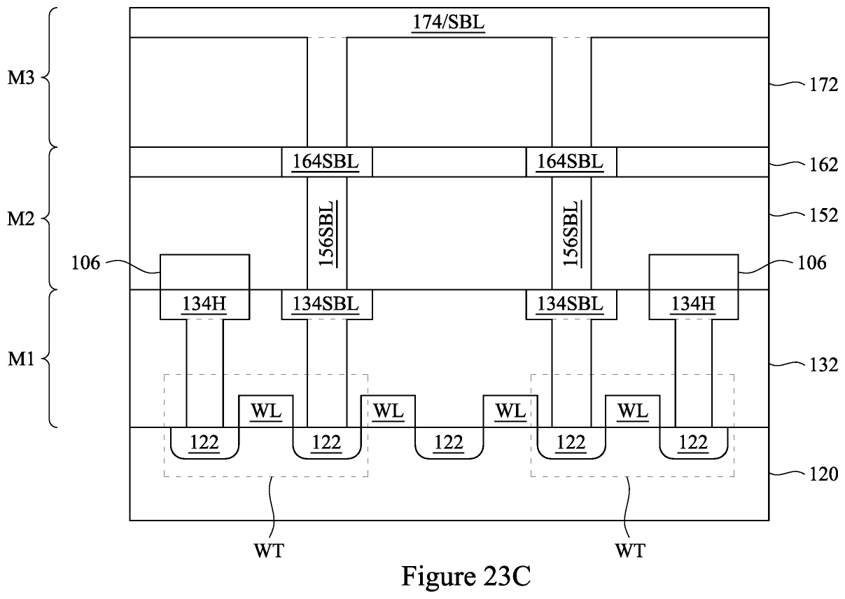

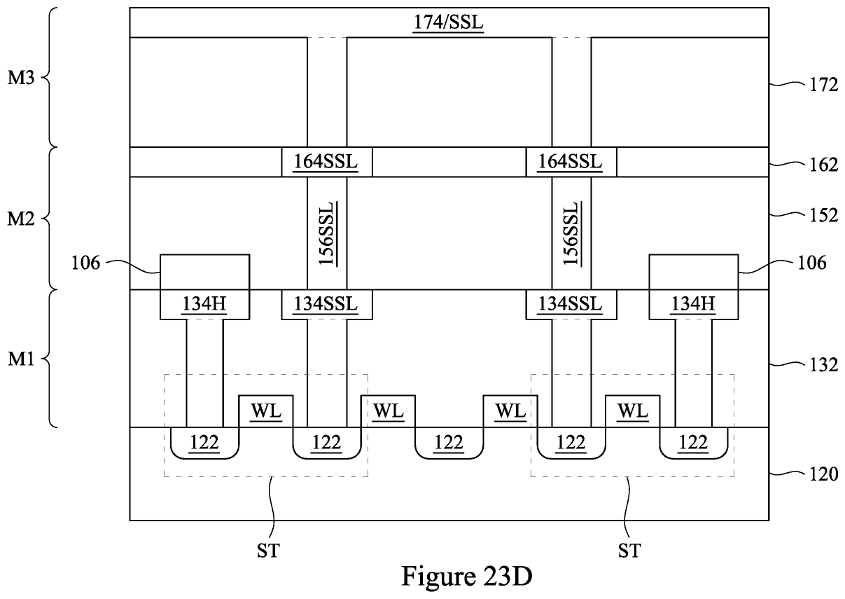

FIGS. 16A-23D are view of intermediate stages in the manufacturing of the memory device 100 of FIG. 15, in accordance with some embodiments. Specifically, the manufacturing of the interconnect structure 130 (including the MTJs 108 and the SOT lines 106) of FIG. 15 is shown. FIGS. 16A, 17A, 18A, 19A, 20A, 21A, 22A, and 23A are three-dimensional views of a portion of the memory device 100 of FIG. 15 (specifically, one side of the mirrored structure). FIGS. 16B, 17B, 18B, 19B, 20B, 21B, 22B, and 23B are cross-sectional views shown along reference cross-section B-B′ in FIG. 15. FIG. 23C is a cross-sectional view shown along reference cross-section C-C′ in FIG. 15. FIG. 23D is a cross-sectional view shown along reference cross-section D-D′ in FIG. 15.

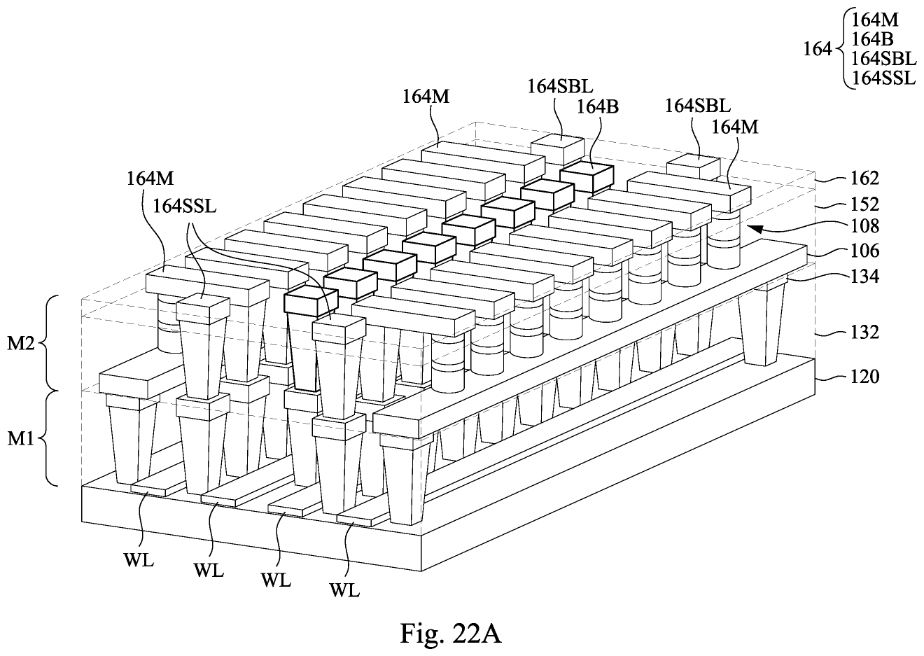

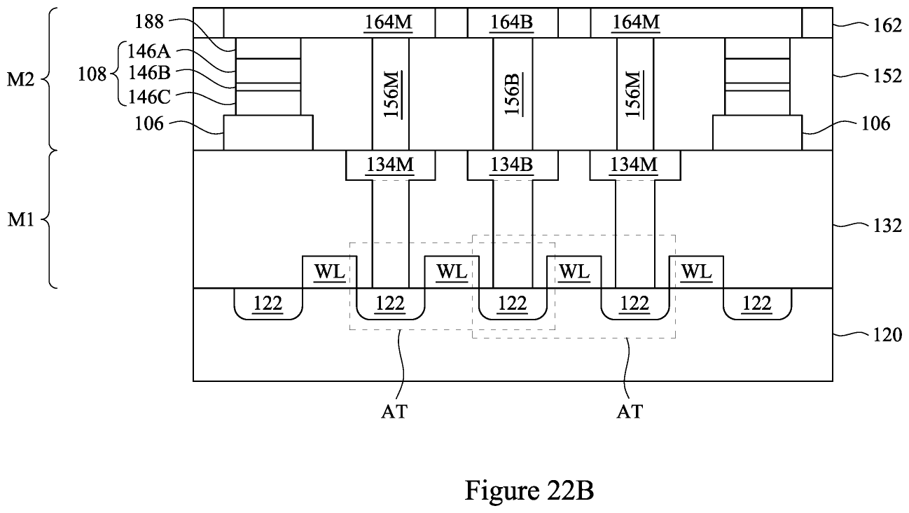

In FIGS. 16A-16B, a semiconductor substrate 120 is received or formed. The semiconductor substrate 120 includes devices (previously described), which may be formed using any acceptable front end of line (FEOL) process. The devices include the write transistor WT, source transistor ST, and access transistors AT (see FIGS. 22B-23D).

A first metallization layer M1 of the interconnect structure 130 is formed over the semiconductor substrate 120. The first metallization layer M1 may be formed using any acceptable back end of line (BEOL) process. For example, an IMD 132 may be formed over the semiconductor substrate 120, and a metallization pattern 134 may be formed in the IMD 132. The IMD 132 and the metallization pattern 134 may be formed in a similar manner as described for FIGS. 4A-4B.

The metallization pattern 134 includes metal pads and metal vias that are electrically connected to the devices of the semiconductor substrate 120. A subset of the metal pads/vias 134M will be subsequently utilized for connecting overlying MTJs to the access transistors AT (see FIG. 23B). A subset of the metal pads/vias 134B will be subsequently utilized for connecting overlying bit lines BL to the access transistors AT (see FIG. 23B). A subset of the metal pads/vias 134SBL will be subsequently utilized for connecting overlying string bit lines SBL to the write transistors WT (see FIG. 23C). A subset of the metal pads/vias 134SSL will be subsequently utilized for connecting overlying string source lines SSL to the source transistors ST (see FIG. 23D). A subset of the metal pads/vias 134H will be subsequently utilized for connecting overlying SOT lines to the write transistors WT (see FIG. 23C) and source transistors ST (see FIG. 23D).

The metal vias 134M/134B are arranged in rows, with each row of metal vias 134B between two rows of the metal vias 134M. A group G₁ of the metal vias 134M/134B is between a group G2 of the metal vias 134SBL/134H and a group G3 of the metal vias 134SSL/134H. Forming the metal vias with such a layout allows the features for each string of unit cells 102 (see FIG. 1) to be interconnected in a small area.

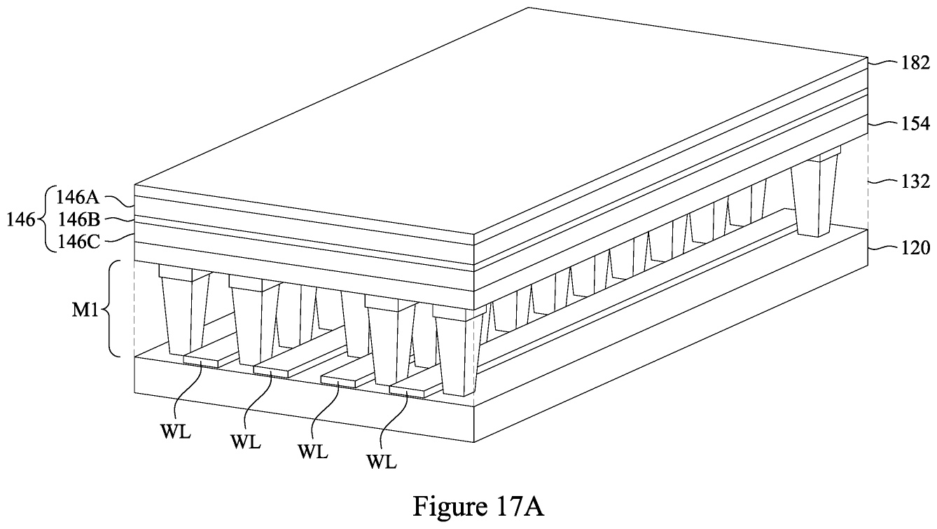

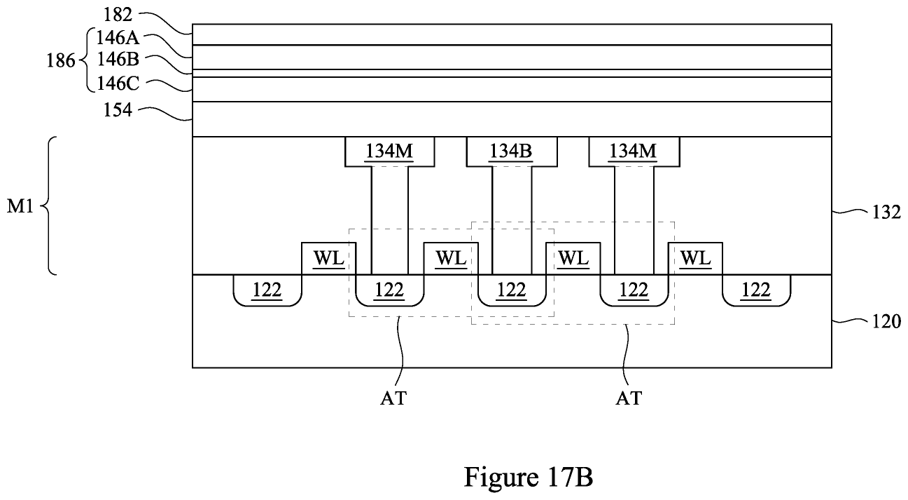

In FIGS. 17A-17B, an electrode layer 154 is formed on the IMD 132 and the exposed portions of the metallization pattern 134. The electrode layer 154 may be formed in a similar manner as described for FIGS. 10A-10B.

An MTJ film stack 146 (including a fixed layer 146A, a barrier layer 146B, and a free layer 146C) is formed on the electrode layer 154. The MTJ film stack 146 may be formed in a similar manner as described for FIGS. 6A-6B, except the order of the layers may be reversed.

An electrode layer 182 is formed on the MTJ film stack 146. The electrode layer 182 may be formed of any suitable conductive material, such as copper, aluminum, tungsten, silver, and combinations thereof, or the like, which may be formed by plating (e.g., electroplating or electroless plating), deposition (e.g., PVD), combinations thereof, or the like.

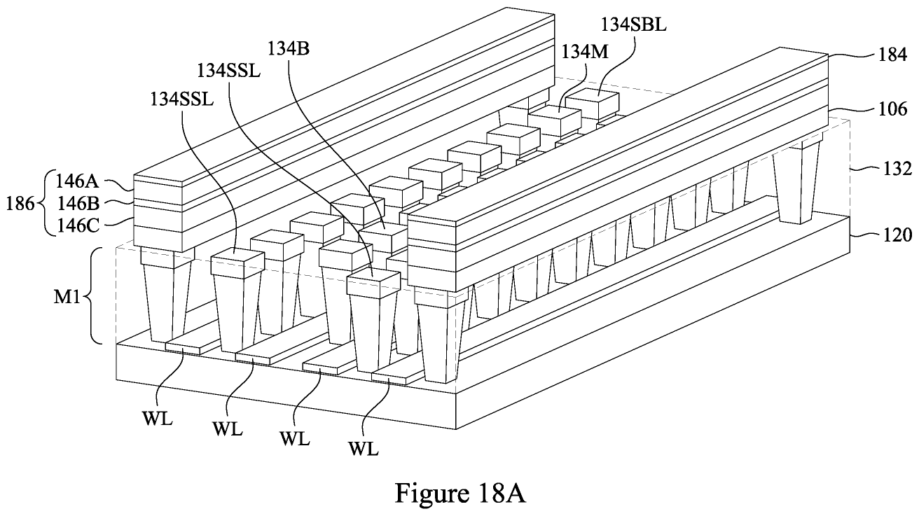

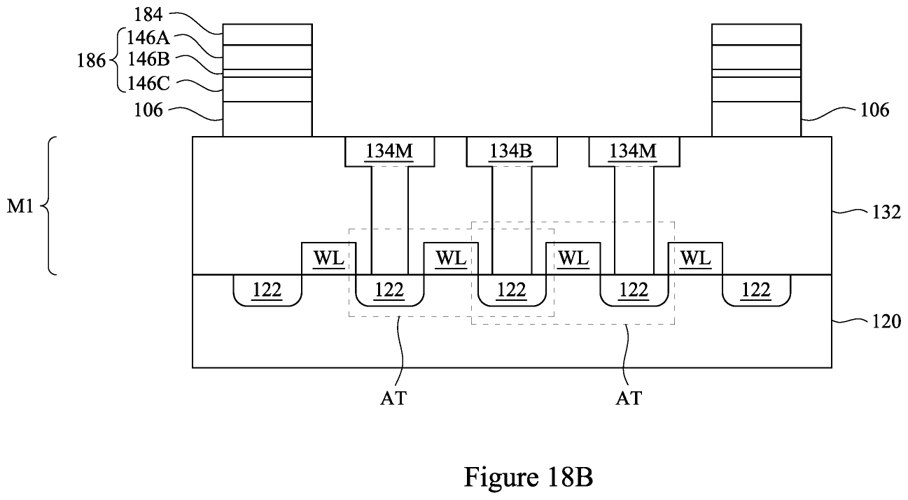

In FIGS. 18A-18B, the electrode layer 182, the MTJ film stack 146, and the electrode layer 154 are patterned to form electrode strips 184, MTJ film strips 186, and SOT lines 106, respectively. The patterning may be by acceptable photolithography and etching processes. The etching may be anisotropic. The SOT lines 106 are formed on (and are connected to) the metal pads/vias 134H. The metal pads/vias 134M/134B/134SBL/134SSL are exposed by the patterning of the electrode layer 182, the MTJ film stack 146, and the electrode layer 154.

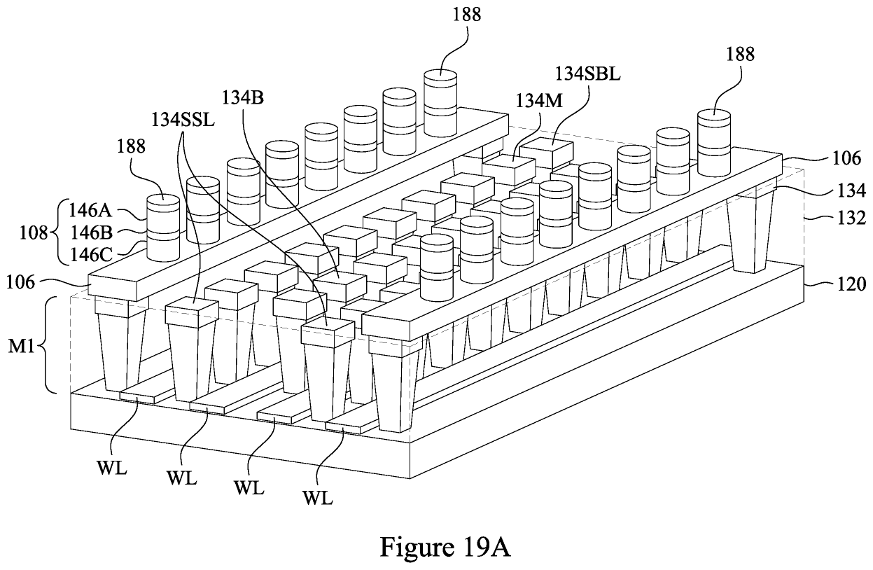

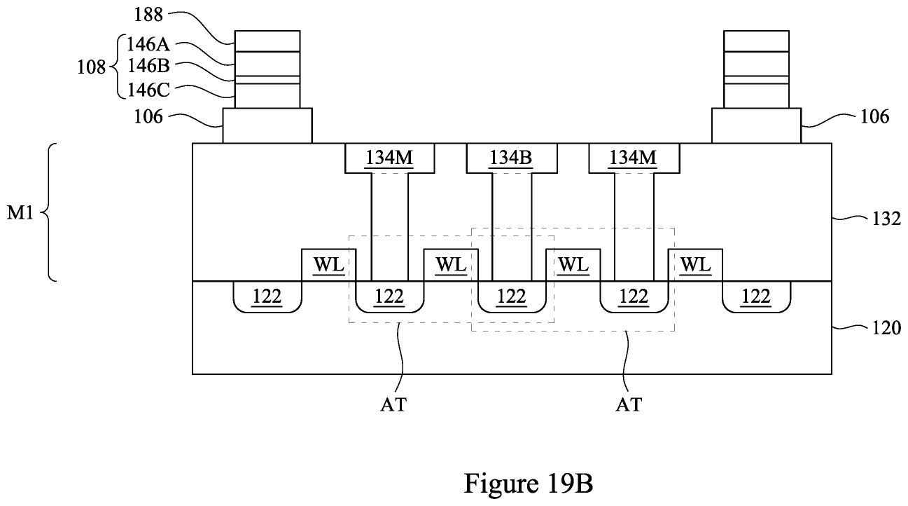

In FIGS. 19A-19B, the electrode strips 184 and the MTJ film strips 186 are patterned to form, respectively, top electrodes 188 and MTJs 108. The patterning may be performed in a similar manner as described for FIGS. 7A-7B. Each MTJ 108 includes a patterned portion of the MTJ film stack 146 (including patterned portions of the fixed layer 146A, the barrier layer 146B, and the free layer 146C). Each top electrode 188 is formed on a respective MTJ 108.

In some embodiments, the step of FIGS. 18A-18B is reversed with the step of FIGS. 19A-19B. Specifically, the electrode layer 182 and the MTJ film stack 146 may first be patterned to form, respectively, the top electrodes 188 and the MTJ film stacks 146. Subsequently, the electrode layer 154 may be patterned to form the SOT lines 106.

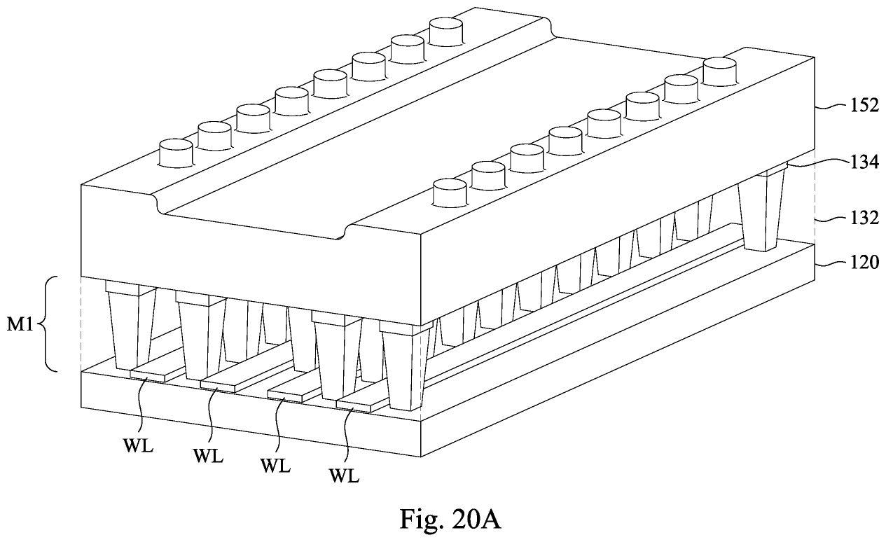

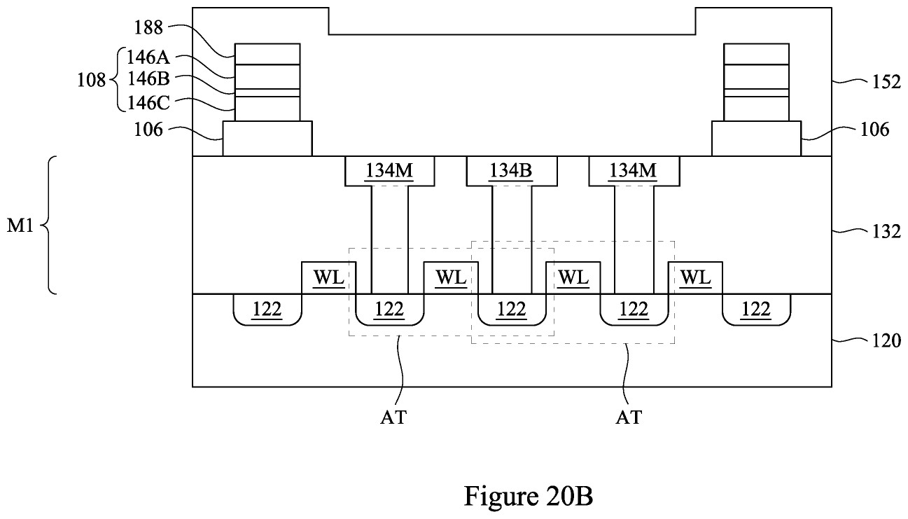

In FIGS. 20A-20B, an IMD 152 is formed on the top electrodes 188, the MTJs 108, and the IMD 132. The IMD 152 may be formed in a similar manner as described for FIGS. 8A-8B. The IMD 152 is formed to a large enough thickness that the top electrodes 188 are buried.

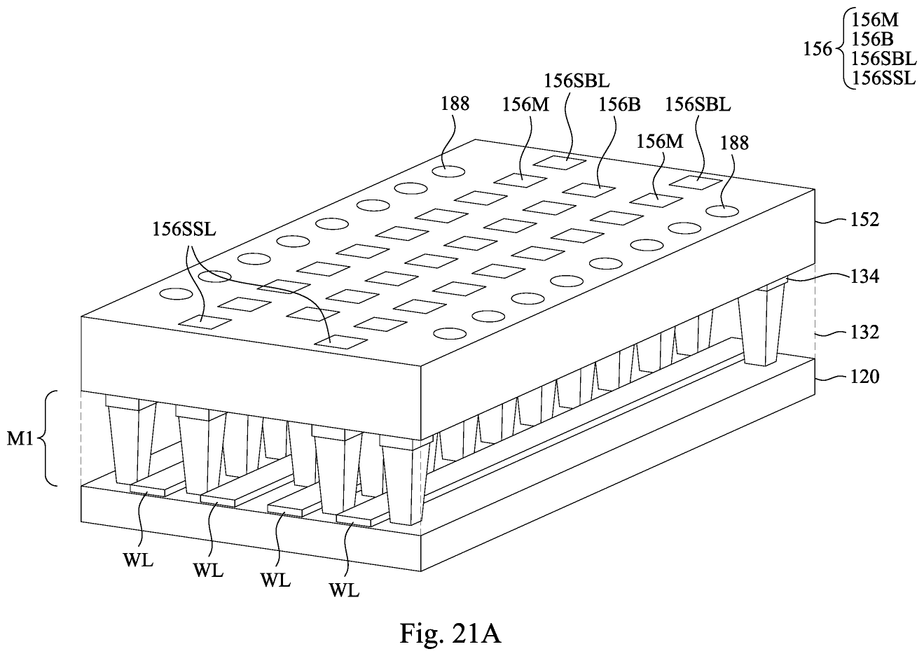

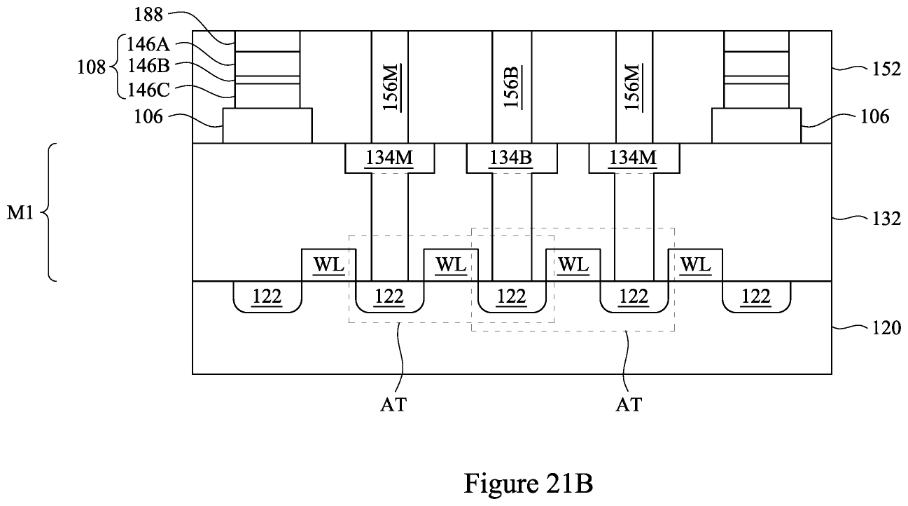

In FIGS. 21A-21B, a metallization pattern 156 is formed in the IMD 152. The metallization pattern 156 may be formed of any suitable conductive material, such as copper, aluminum, tungsten, silver, and combinations thereof, or the like. The metallization pattern 156 may formed by a damascene process, such as a single damascene process, a dual damascene process, or the like. After the damascene process, the top surfaces of the metallization pattern 156 and the top electrodes 188 are substantially coplanar (within process variations) with the top surface of the IMD 152.

The metallization pattern 156 includes metal vias that are electrically connected to the metallization pattern 134. A subset of the metal vias 156M are connected to the metal pads/vias 134M. A subset of the metal vias 156B are connected to the metal pads/vias 134B. A subset of the metal vias 156SBL are connected to the metal pads/vias 134SBL. A subset of the metal vias 156SSL are connected to the metal pads/vias 134SSL.

In FIGS. 22A-22B, an IMD 162 is formed on the IMD 152. The IMD 162 may be formed in a similar manner as described for FIGS. 12A-12B.

A metallization pattern 164 is formed in the IMD 162, thereby completing formation of a second metallization layer M2 of the interconnect structure 130. The metallization pattern 164 may be formed in a similar manner as described for FIGS. 13A-13B.

The metallization pattern 164 includes metal lines that are electrically connected to the metallization pattern 156 and the top electrodes 188. A subset of the metal lines 164M connect the metal vias 156M to the top electrodes 188. A subset of the metal lines 164B are connected to the metal vias 156B. A subset of the metal lines 164SBL are connected to the metal vias 156SBL. A subset of the metal lines 164SSL are connected to the metal vias 156SSL.

In FIGS. 23A-23D, an third metallization layer M3 of the interconnect structure 130 is formed over the second metallization layer M2. The third metallization layer M3 may be formed using any acceptable back end of line (BEOL) process. For example, an IMD 172 may be formed over the IMD 162, and a metallization pattern 174 may be formed in the IMD 172. The IMD 172 and the metallization pattern 174 may be formed in a similar manner as described for FIGS. 14A-14D.

The metallization pattern 174 includes metal lines and metal vias that are electrically connected to the metallization pattern 164 (see FIG. 13A). The metal lines include the bit lines BL, the string bit lines SBL, and the string source lines SSL, each of which are substantially perpendicular to the word lines WL (e.g., to the gate structures of the devices of the semiconductor substrate 120). The bit lines BL are connected to the metal lines 164B. The string bit lines SBL are connected to the metal vias 164SBL. The string source lines SSL are connected to the metal vias 164SSL. The metallization pattern 174 may also include word lines (not separately illustrated) that are connected to the word lines WL (e.g., to the gate structures of the devices of the semiconductor substrate 120).

The metallization patterns 134, 156, 164, 174 interconnect the MTJs 108, the SOT lines 106, and the devices of the semiconductor substrate 120 to form the memory device 100. Therefore, an integrated circuit implementing the memory device 100 of FIG. 1 is formed. As shown by FIG. 23B, the metal pads/vias 134B, the metal vias 156B, and the metal lines 164B collectively connect the bit lines BL to source/drain regions 122 of the access transistors AT. As also shown by FIG. 23B, the metal pads/vias 134M, the metal vias 156M, and the metal lines 164M collectively connect the top electrodes 188 (and thus the MTJs 108) to source/drain regions 122 of the access transistors AT. As shown by FIG. 23C, the metal pads/vias 134SBL, the metal vias 156SBL, and the metal lines 164SBL collectively connect the string bit lines SBL to source/drain regions 122 of the write transistors WT. As shown by FIG. 23D, the metal pads/vias 134SSL, the metal vias 156SSL, and the metal lines 164SSL collectively connect the string source lines SSL to source/drain regions 122 of the source transistors ST. As shown by FIGS. 23C and 23D, the metal pads/vias 134H connect the SOT lines 106 to source/drain regions 122 of the write transistors WT and the source transistors ST.

In the foregoing embodiment, the interconnect structure 130 includes multiple metallization layers M1-M3; the SOT lines 106 and the MTJs 108 are formed the second metallization layer M2; and the bit lines BL, the string bit lines SBL, and the string source lines SSL are formed in the third metallization layer M3. It should be appreciated that the interconnect structure 130 may include other quantities of metallization layers, and that the memory device features may be formed in other layers.

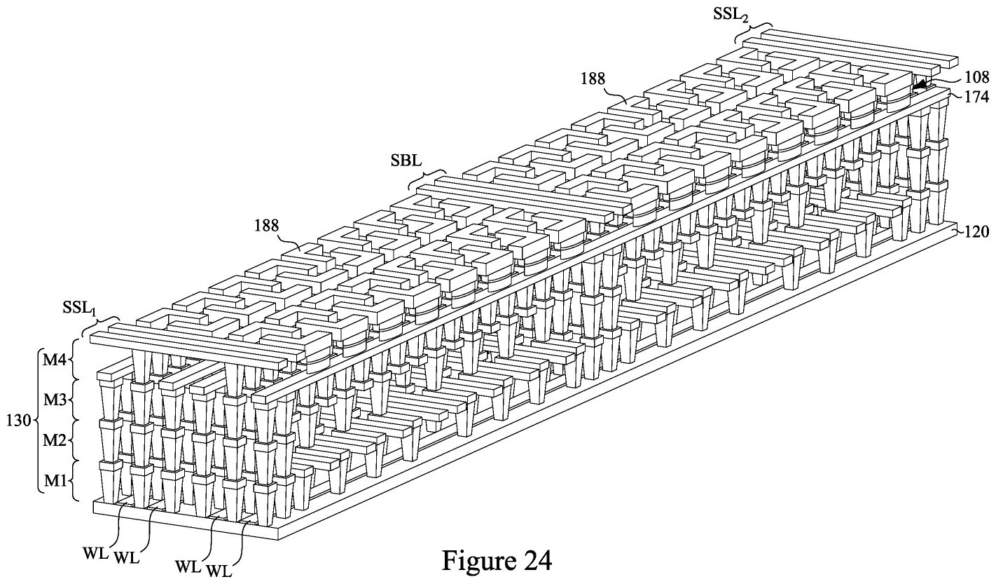

FIG. 24 is a three-dimensional view of a memory device 100, in accordance with some embodiments. This embodiment is similar to the embodiment of FIG. 15, except the SOT lines 106, the MTJs 108, the string bit lines SBL, and the string source lines SSL are formed in the a fourth metallization layer M4 of the interconnect structure 130. The bit lines BL are formed in the first metallization layer M1. The respective components may be formed by similar processes as previously described, except those processes are performed to form the components in the desired layer. Additionally, in this embodiment, the top electrodes 188 have an interdigitated layout, which allows the MTJs 108 to be formed to a larger size, which may be advantages for some types of MTJs such as in-plane MTJs.

Embodiments may achieve advantages. Forming the SOT lines 106 and then patterning the MTJs 108 directly on the SOT lines 106 may be advantageous. Specifically, manufacturing complexity may be reduced. Additionally, forming the metallization patterns 134, 156, 164, 174 with the previously described layout allows the memory device 100 to be formed to a greater density. Specifically, each string of unit cells 102 (see FIG. 1) only utilizes one write transistor WT and one SOT line 106, as compared to other STT-assisted SOT-MRAM devices where each MTJ 108 in a string has its own SOT line and its own write transistor. Write transistors may be large, and so reducing the quantity of write transistors in the memory device 100 allows for an increase in density. In some embodiments, each unit cell 102 occupies as little as 10 or 12 times the minimum feature size of the memory device 100.

In an embodiment, a device includes: a spin-orbit torque line; a write transistor coupling a first end of the spin-orbit torque line to a first source line; a source transistor coupling a second end of the spin-orbit torque line to a second source line; and a plurality of magnetic tunnel junctions coupled to the spin-orbit torque line, the magnetic tunnel junctions being in a current path between the write transistor and the source transistor. In some embodiments, the device further includes: access transistors coupling the magnetic tunnel junctions to bit lines, each of the access transistors coupling a respective one of the magnetic tunnel junctions to a respective one of the bit lines. In some embodiments, the device further includes: a current source coupled to the first source line and the second source line, the current source configured to provide a first write current to the spin-orbit torque line during a programming operation; and a bit line driver coupled to the bit lines, the bit line driver configured to provide second write currents to the bit lines during the programming operation. In some embodiments of the device, the current source provides the first write current to the spin-orbit torque line by setting the first source line to a higher voltage than the second source line. In some embodiments, the device further includes: a bit line driver coupled to the bit lines, the bit line driver configured to provide read currents during a read operation. In some embodiments of the device, the bit line driver provides the read currents to the bit lines by setting a first subset of the bit lines to a greater voltage than the second source line and setting a second subset of the bit lines to a lesser voltage than the second source line. In some embodiments of the device, gates of the access transistors, the write transistor, and the source transistor are coupled to a word line. In some embodiments of the device, the magnetic tunnel junctions are in-plane magnetic tunnel junctions. In some embodiments of the device, the magnetic tunnel junctions are perpendicular magnetic tunnel junctions. In some embodiments of the device, the spin-orbit torque line includes a heavy metal and a light transition metal. In some embodiments of the device, the heavy metal includes platinum, palladium, or tungsten, and where the light transition metal includes scandium, titanium, vanadium, chromium, manganese, iron, cobalt, nickel, or copper.

In an embodiment, a device includes: a first spin-orbit torque line over a semiconductor substrate, the first spin-orbit torque line including an alloy of a heavy metal and a light transition metal; first magnetic tunnel junctions coupled to the first spin-orbit torque line; a first interconnect coupling the first spin-orbit torque line to the semiconductor substrate; and a second interconnect coupling the first spin-orbit torque line to the semiconductor substrate, the first magnetic tunnel junctions spaced apart along the first spin-orbit torque line between the first interconnect and the second interconnect. In some embodiments of the device, the first magnetic tunnel junctions are disposed below the first spin-orbit torque line. In some embodiments, the device further includes: third interconnects beneath the first magnetic tunnel junctions, the third interconnects coupling the first magnetic tunnel junctions to the semiconductor substrate. In some embodiments of the device, the first magnetic tunnel junctions are disposed above the first spin-orbit torque line. In some embodiments, the device further includes: third interconnects above the first magnetic tunnel junctions, the third interconnects coupling the first magnetic tunnel junctions to the semiconductor substrate. In some embodiments, the device further includes: a second spin-orbit torque line over the semiconductor substrate; second magnetic tunnel junctions coupled to the second spin-orbit torque line; bit lines above the first magnetic tunnel junctions and the second magnetic tunnel junctions; and third interconnect between the first spin-orbit torque line and the second spin-orbit torque line, the third interconnect coupling the bit lines to the semiconductor substrate.

In an embodiment, a method includes: forming a first metallization layer of an interconnect structure over a semiconductor substrate, the first metallization layer including first interconnects; forming a second metallization layer of the interconnect structure over the first metallization layer, the second metallization layer including a spin-orbit torque line, magnetic tunnel junctions, and second interconnects, each of the magnetic tunnel junctions contacting a respective portion of the spin-orbit torque line; and forming a third metallization layer of the interconnect structure over the second metallization layer, the third metallization layer including bit lines, the first interconnects and the second interconnects interconnecting the bit lines, the magnetic tunnel junctions, the spin-orbit torque line, and devices of the semiconductor substrate to form a memory device. In some embodiments of the method, the magnetic tunnel junctions are formed below the spin-orbit torque line. In some embodiments of the method, the magnetic tunnel junctions are formed above the spin-orbit torque line.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a spin-orbit torque line;
a write transistor coupling a first end of the spin-orbit torque line to a first source line;
a source transistor coupling a second end of the spin-orbit torque line to a second source line; and
a plurality of magnetic tunnel junctions coupled to the spin-orbit torque line, the magnetic tunnel junctions being in a current path between the write transistor and the source transistor.

2. The device of claim 1 further comprising:
access transistors coupling the magnetic tunnel junctions to bit lines, each of the access transistors coupling a respective one of the magnetic tunnel junctions to a respective one of the bit lines.

3. The device of claim 2 further comprising:
a current source coupled to the first source line and the second source line, the current source configured to provide a first write current to the spin-orbit torque line during a programming operation; and
a bit line driver coupled to the bit lines, the bit line driver configured to provide second write currents to the bit lines during the programming operation.

4. The device of claim 3, wherein the current source provides the first write current to the spin-orbit torque line by setting the first source line to a higher voltage than the second source line.

5. The device of claim 2 further comprising:
a bit line driver coupled to the bit lines, the bit line driver configured to provide read currents during a read operation.

6. The device of claim 5, wherein the bit line driver provides the read currents to the bit lines by setting a first subset of the bit lines to a greater voltage than the second source line and setting a second subset of the bit lines to a lesser voltage than the second source line.

7. The device of claim 2, wherein gates of the access transistors, the write transistor, and the source transistor are coupled to a word line.

8. The device of claim 1, wherein the magnetic tunnel junctions are in-plane magnetic tunnel junctions.

9. The device of claim 1, wherein the magnetic tunnel junctions are perpendicular magnetic tunnel junctions.

10. The device of claim 1, wherein the spin-orbit torque line comprises a heavy metal and a light transition metal.

11. The device of claim 10, wherein the heavy metal comprises platinum, palladium, or tungsten, and wherein the light transition metal comprises scandium, titanium, vanadium, chromium, manganese, iron, cobalt, nickel, or copper.

12. A device comprising:
a first spin-orbit torque line over a semiconductor substrate, the first spin-orbit torque line comprising an alloy of a heavy metal and a light transition metal;
first magnetic tunnel junctions coupled to the first spin-orbit torque line;
a first interconnect coupling the first spin-orbit torque line to the semiconductor substrate; and
a second interconnect coupling the first spin-orbit torque line to the semiconductor substrate, the first magnetic tunnel junctions spaced apart along the first spin-orbit torque line between the first interconnect and the second interconnect.

13. The device of claim 12, wherein the first magnetic tunnel junctions are disposed below the first spin-orbit torque line.

14. The device of claim 13 further comprising:
third interconnects beneath the first magnetic tunnel junctions, the third interconnects coupling the first magnetic tunnel junctions to the semiconductor substrate.

15. The device of claim 12, wherein the first magnetic tunnel junctions are disposed above the first spin-orbit torque line.

16. The device of claim 13 further comprising:
third interconnects above the first magnetic tunnel junctions, the third interconnects coupling the first magnetic tunnel junctions to the semiconductor substrate.

17. The device of claim 12 further comprising:
a second spin-orbit torque line over the semiconductor substrate;
second magnetic tunnel junctions coupled to the second spin-orbit torque line;
bit lines above the first magnetic tunnel junctions and the second magnetic tunnel junctions; and
third interconnect between the first spin-orbit torque line and the second spin-orbit torque line, the third interconnect coupling the bit lines to the semiconductor substrate.

18. A method comprising:
forming a first metallization layer of an interconnect structure over a semiconductor substrate, the first metallization layer comprising first interconnects;
forming a second metallization layer of the interconnect structure over the first metallization layer, the second metallization layer comprising a spin-orbit torque line, magnetic tunnel junctions, and second interconnects, each of the magnetic tunnel junctions contacting a respective portion of the spin-orbit torque line; and
forming a third metallization layer of the interconnect structure over the second metallization layer, the third metallization layer comprising bit lines, the first interconnects and the second interconnects interconnecting the bit lines, the magnetic tunnel junctions, the spin-orbit torque line, and devices of the semiconductor substrate to form a memory device.

19. The method of claim 18, wherein the magnetic tunnel junctions are formed below the spin-orbit torque line.

20. The method of claim 18, wherein the magnetic tunnel junctions are formed above the spin-orbit torque line.
